(19) United States
(12) Patent Application Publication
(10) Pub. No.: US 2009/0250094 A1
(43) Pub. Date: Oct. 8, 2009

(54) METHOD AND SYSTEM FOR LIGHT RAY CONCENTRATION

(75) Inventors: John Henry Robison, Burlingame, CA (US); Daniel T. Colbert, Santa Barbara, CA (US); John G. Pender, Fairbanks, AK (US); Dwight P. Duston, Laguna Niguel, CA (US); Joshua N. Haddock, Roanoke, VA (US)

Correspondence Address: FISH & RICHARDSON P.C., PO BOX 1022, MINNEAPOLIS, MN, 55440-1022, US

(73) Assignee: SOLBEAM, INC., Laguna Niguel, CA (US)

(21) Appl. No.: 12/302,706

(22) PCT Filed: May 31, 2007
(86) PCT No.: PCT/US07/70163

§ 371 Date: Apr. 20, 2009

(30) Foreign Application Priority Data
Jun. 1, 2006 (US) 60809812
Mar. 7, 2007 (US) 60905303
Apr. 4, 2007 (US) 60907496

(51) Int. Cl. H01L 31/052

(52) U.S. Cl. 136/246

(57) ABSTRACT

Systems and techniques for light ray concentration. In one aspect, a solar concentration assembly includes an array of light focusing elements and an array of photovoltaic devices positioned beneath the array of light focusing elements. The arrays of light focusing elements and photovoltaic devices are spaced from one another and configured to concentrate solar rays incident on the light focusing elements to the photovoltaic elements, such that solar ray communication is maintained as an angle of the assembly relative to the sun is altered by movement of the sun during a day and wherein the angle is an oblique angle for the majority of the day.

### TECHNICAL FIELD

This disclosure generally relates to techniques and assemblies for concentrating light rays.

### BACKGROUND

Focusing light rays emanating from either a natural or an artificial source can be useful for various different applications. For example, steering solar rays to direct them toward a photovoltaic cell or to direct them toward a light focusing element, which then focuses the solar rays on a photovoltaic cell, can be useful in solar energy collection applications. Generally, a photovoltaic cell (or other device for capturing solar energy) is a device that captures solar radiation and converts the radiation into electric potential or current. A conventional photovoltaic cell is typically configured as a flat substrate supporting an absorbing layer, which captures impinging solar radiation, and electrodes, or conducting layers, which serve to transport electrical charges created within the cell.

A solar concentrator is a light focusing element that can be employed to multiply the amount of sunlight, i.e., the solar flux, impinging on a photovoltaic cell. A solar energy collection assembly, or array, can be mounted on a moveable platform, in an attempt to keep the absorbing layer directed approximately normal to the solar rays as the sun tracks the sky over the course of a day. If a light focusing element, such as a lens or curved mirror, is included in the solar energy collection assembly to focus the solar rays toward the photovoltaic cells, the assembly's position can be adjusted in an attempt to keep the receiving surface of the light focusing element directed approximately normal to the solar rays. The platform can be moved manually or automatically by mechanical means, and various techniques can be employed to track the sun.

In general, light rays refract upon passing through a triangular prism at a fixed angle that depends on the prism apex angle, wavelength of light, the refractive index of the prism material, and the incident angle of the light rays, assuming the light rays are not totally internally reflected inside the prism. A prism used together with a layer of liquid crystal positioned between two contiguous electrodes, such as that described in U.S. Pat. No. 6,958,868, can refract light of a given wavelength at many different angles, because the refractive index of the liquid crystal layer can be varied by varying the strength of electrical field across the layer. The refractive angle of the light rays, as they pass through the prism assembly, can therefore be controlled within some limitations by varying the applied electric field, thereby steering the light rays within some angular range. A solar energy collection assembly employing such a prism assembly to steer solar rays toward a light focusing element is described in U.S. Pat. No. 6,958,868.

### SUMMARY

Techniques and assemblies for steering light rays are provided. In general, in one aspect, the invention features a solar concentration assembly including an array of light focusing elements being multiple light focusing elements arranged near one another and an array of photovoltaic devices positioned beneath the array of light focusing elements, being multiple photovoltaic devices arranged near one another. The arrays of light focusing elements and photovoltaic devices are spaced from one another and configured to concentrate solar rays incident on the light focusing elements to the photovoltaic elements such that solar ray communication is maintained as an angle of the assembly relative to the sun is altered by movement of the sun during a day and wherein the angle comprises an oblique angle for the majority of the day.

Implementations of the invention can include one or more of the following. Maintaining optical communication can be effected using an electro-optic layer included in the light focusing elements. In another implementation, maintaining optical communication can be effected by relative translational movement between the array of light focusing elements and the array of photovoltaic elements. The spacing between the array of light focusing elements and the array of photovoltaic devices can be adjustable. At least one of the arrays can be configured to move in two dimensions within a plane of the array. Each array is positioned in a plane and each array can be adjustable by intra-plane and inter-plane movement. The array of light focusing elements and the array of photovoltaic devices can be both two-dimensional arrays including m elements in a first direction and n elements in a second direction, where m and n are whole numbers.

The array of light focusing elements can be stationary with respect to a terrestrial surface. The array of photovoltaic devices can be stationary with respect to a terrestrial surface. The array of light focusing elements can include one or more Fresnel lenses and/or can include one or more f-theta lenses.

The assembly can be configured such that at a first time of the day solar rays are incident on a receiving surface of a light focusing element at a substantially right angle, exit an opposite surface of the light focusing element and focus on a first photovoltaic device in a first position beneath the light focusing element, and at a second time during the day the solar rays are incident on the receiving surface of the light focusing element at an oblique angle, exit the opposite surface of the light focusing element and focus on a second photovoltaic device at a second, different position. At a third time during the day the solar rays can be incident on the receiving surface of the light focusing element at an oblique angle, exit the opposite surface of the light focusing element and focus on a third photovoltaic device at a third, different position.

In one implementation, the assembly includes a translation mechanism configured to translate the array of photovoltaic devices relative to the array of light focusing elements. Each photovoltaic device can have a home position and a maximum translation position. The translation mechanism can be configured to translate the photovoltaic devices from the home position to the maximum translation position and return the photovoltaic devices to the home position. The home position can be a position such that the photovoltaic device is substantially axially aligned with a light focusing element positioned above the photovoltaic device and the maximum translation position can be a position approaching the home position of an adjacent photovoltaic device. In another implementation, the home position can be a position such that the photovoltaic device is substantially axially aligned with a light focusing element positioned above the photovoltaic device and the maximum translation position can be a position approximately half way between the home positions of adjacent photovoltaic devices. In yet another implementation, in neither the home position nor the maximum translation position is the photovoltaic device axially aligned with a light focusing element.

The assembly can further include a photovoltaic platform configured to support the array of photovoltaic devices. The photovoltaic platform can be configured to raise and lower the array of photovoltaic devices relative to the array of light focusing elements and/or can be configured to change an angular position of the photovoltaic devices relative to the light focusing elements. In another implementation, the photovoltaic platform can be configured to change the angular position in two dimensions.

In some implementations, one or more light focusing elements include an electro-optic prism operable to provide controllable steering of solar rays incident on the receiving surface of the light focusing element, and a lens arranged in optical communication with the electro-optic prism and positioned to receive and concentrate the solar rays after having passed through the electro-optic prism. Solar rays incident on the receiving surface of the light focusing element between an angle of −θ to θ from an axis perpendicular to the receiving surface can be controllably steered by the electro-optic prism such that said solar rays are incident on the lens at a substantially right angle to a receiving surface of the lens and are focused by the lens on a first photovoltaic device. Solar rays incident on the receiving surface of the light focusing element between angles of −3θ to −θ0 and θ to 3θ from an axis perpendicular to the receiving surface can be controllably steered by the electro-optic prism such that said solar rays are incident on the lens at an oblique angle and focused by the lens on a neighboring second photovoltaic device.

The electro-optic prism can include a first electrode including multiple substantially parallel linear electrodes positioned on a first substrate, a reference electrode positioned on a second substrate, and an electro-optic material positioned between the first electrode and the reference electrode. The electro-optic material can be a layer having a substantially uniform thickness. In one implementation, the electro-optic material is a liquid crystal material. The electro-optic material can be positioned between the first electrode and the reference electrode such that, where separately controllable voltages are provided to at least some of the linear electrodes, a gradient electric field is provided within the electro-optic material to cause the electro-optic material to have a refractive index gradient. The refractive index gradient can be controlled by varying the magnitude of the separately controllable voltages provided to at least some of the linear electrodes. Steering of solar rays incident on the electro-optic prism can be controllable by controlling the refractive index gradient.

The assembly can further include a set of corrective optics orientated substantially perpendicular to the arrays of light focusing elements and photovoltaic devices and positioned periodically in a space therebetween. In one example, the corrective optics are Fresnel lenses.

In general, in another aspect, the invention features a light energy collection system including an array of light focusing elements, an array of photovoltaic devices and a translation mechanism. The translation mechanism is configured to translate the array of light focusing elements and the array of photovoltaic devices relative to one another based on an incidence angle of light rays impinging on receiving surfaces of the light focusing elements such that the light rays can be continually focused by the light focusing elements on a photovoltaic device included in the array of photovoltaic devices as a source of the light rays moves relative to the system.

Implementations of the invention can include one or more of the following features. The array of light focusing elements can be fixed and the translation mechanism can be configured to translate the array of photovoltaic devices. The array of photovoltaic devices can be fixed and the translation mechanism can be configured to translate the array of light focusing elements. In another implementation, neither the array of light focusing elements nor the array of photovoltaic devices is fixed and the translation mechanism is configured to translate both arrays.

Each photovoltaic device can have a home position and a maximum translation position. The translation mechanism can be configured to translate the photovoltaic devices from the home position to the maximum translation position and return the photovoltaic devices to the home position. The home position can be a position such that the photovoltaic device is substantially axially aligned with a light focusing element positioned above the photovoltaic device and the maximum translation position can be a position approaching the home position of an adjacent photovoltaic device. In another implementation, the home position can be a position such that the photovoltaic device is substantially axially aligned with a light focusing element positioned above the photovoltaic device and the maximum translation position can be a position approximately half way between the home positions of neighboring photovoltaic devices. In another implementation, in neither the home position nor the maximum translation position is the photovoltaic device axially aligned with a light focusing element.

The assembly can further include a photovoltaic platform configured to support the array of photovoltaic devices. The photovoltaic platform can be configured to raise and lower the array of photovoltaic devices relative to the array of light focusing elements. The photovoltaic platform can be configured to change an angular position of the photovoltaic devices relative to the light focusing elements. In another implementation, the photovoltaic platform can be configured to change the angular position in two dimensions.

In general, in another aspect, the invention features a method of concentrating light rays from a moving light source onto a photovoltaic device. Light rays are received on receiving surfaces of light focusing elements forming an array of light focusing elements. The light rays are concentrated onto a photovoltaic device included in an array of photovoltaic devices positioned beneath the array of light focusing elements. As an incidence angle of the light rays on the receiving surfaces changes due to movement of the light source, the array of light focusing elements is translated relative to the array of photovoltaic devices such that the light rays remain impingent on a photovoltaic device.

Implementations of the invention can include one or more of the following features. The array of light focusing elements can be fixed and the array of photovoltaic devices can be translated. The array of photovoltaic devices can be fixed and the array of light focusing elements can be translated. Translating the array of light focusing elements relative to the array of photovoltaic devices can include translating both arrays. The light rays exiting from a first light focusing element included in the array can be concentrated on a first photovoltaic device when the incidence angle is within a first range of angles and concentrated on a neighboring second photovoltaic device when the incidence angle is within a second range of angles. The light rays from the first light focusing element can be concentrated on a third photovoltaic device adjacent to the second photovoltaic device when the incidence angle is within a third range of angles.

In general, in another aspect, the invention features a method of concentrating light rays from a moving light source onto a photovoltaic device. Light rays are received on receiving surfaces of light focusing elements forming an array of light focusing elements. The light rays are concentrated onto a photovoltaic device included in an array of photovoltaic devices positioned beneath the array of light focusing elements. The light focusing elements include an electro-optic prism and a lens, where the electro-optic prism is configured to steer light rays incident on the light focusing element so as to impinge on the lens at an angle such that light rays exiting the lens are focused on a photovoltaic device included in the array of photovoltaic devices.

Implementations of the invention can include one or more of the following features. Voltages can be applied to the electro-optic prism to (i) control a refractive index of the electro-optic prism; and (ii) controllably steer the light rays; wherein the electro-optic prism includes a layer of electro-optic material having a substantially uniform thickness. In one example, the electro-optic material is a liquid crystal material. The lens can be a Fresnel lens.

The light rays exiting from a first light focusing element included in the array can be focused on a first photovoltaic device when the incidence angle is within a first range of angles and can be focused on an adjacent second photovoltaic device when the incidence angle is within a second range of angles. The electro-optic prism can be configured to steer light rays incident on a first light focusing element so as to impinge on the lens at approximately normal to an optical axis of the lens when the incidence angle is within a first range of angles. The light rays exiting from the first light focusing element when the incidence angle is within the first range of angles can be incident on a first photovoltaic device positioned beneath and axially aligned with the lens.

The electro-optic prism can be configured to steer light rays incident on the first light focusing element so as to impinge on the lens at an angle oblique to the optical axis of the lens when the incidence angle is within a second range of angles. Light rays exiting from the first light focusing element when the incidence angle is within the second range of angles can be incident on a second photovoltaic device positioned adjacent the first photovoltaic device.

The electro-optic prism can be configured to steer light rays incident on the first light focusing element so as to impinge on the lens at an angle oblique to the optical axis of the lens when the incidence angle is within a third range of angles, where the third range of angles are more oblique than the second range of angles. Light rays exiting from the first light focusing element when the incidence angle is within the third range of angles can be incident on a third photovoltaic device positioned adjacent the second photovoltaic device.

Certain implementations can realize one or more of the following advantages. The embodiments of the solar energy concentration systems described herein do not require complex solar tracking systems to keep the system pointed at the sun as time progresses. By contrast, in one implementation, small translational changes in the relative position of a photovoltaic device array to a light focusing element array are made to capture focused solar rays the focus position changes, requiring less energy and utilizing lighter mechanical components. The solar energy concentration systems can be mounted on non-moving surfaces (such as a rooftop) yet still collect significant portions of the sun's energy throughout the day. Tracking systems in conventional solar concentrators can require that neighboring concentrators be positioned a significant distance from one another, to avoid interference from one tracking system shadowing a neighboring concentrator, and therefore significant amounts of unused roof space. By contrast, the concentration systems described herein overcome this difficulty and can use significant more surface area of a rooftop.

The details of one or more implementations are set forth in the accompanying drawings and the description below. Other features, objects, and advantages will be apparent from the description and drawings, and from the claims.

### DESCRIPTION OF DRAWINGS

The foregoing summary as well as the following detailed description of the preferred implementation(s) will be better understood when read in conjunction with the appended drawings. It should be understood, however, that the disclosure is not limited to the precise arrangements and instrumentalities shown herein. The components in the drawings are not necessarily to scale, emphasis instead being placed upon clearly illustrating the principles of the present disclosure.

FIGS. 1A-1C represent a prior art solar energy collection system.

FIGS. 2A-2B show a system for collecting light rays obliquely incident to light focusing elements.

FIG. 3 illustrates one embodiment of a light collection assembly.

FIGS. 4A-4B show detailed views of a system for collecting light rays obliquely incident to light focusing elements.

FIG. 5 shows a light collection assembly.

FIGS. 6A-6C show a light collection assembly.

FIGS. 7A-7B show f-theta lenses.

FIGS. 8A-8C illustrate the use of an electro-optic layer for light ray steering.

FIG. 9 illustrates the use of an electro-optic layer for light ray steering.

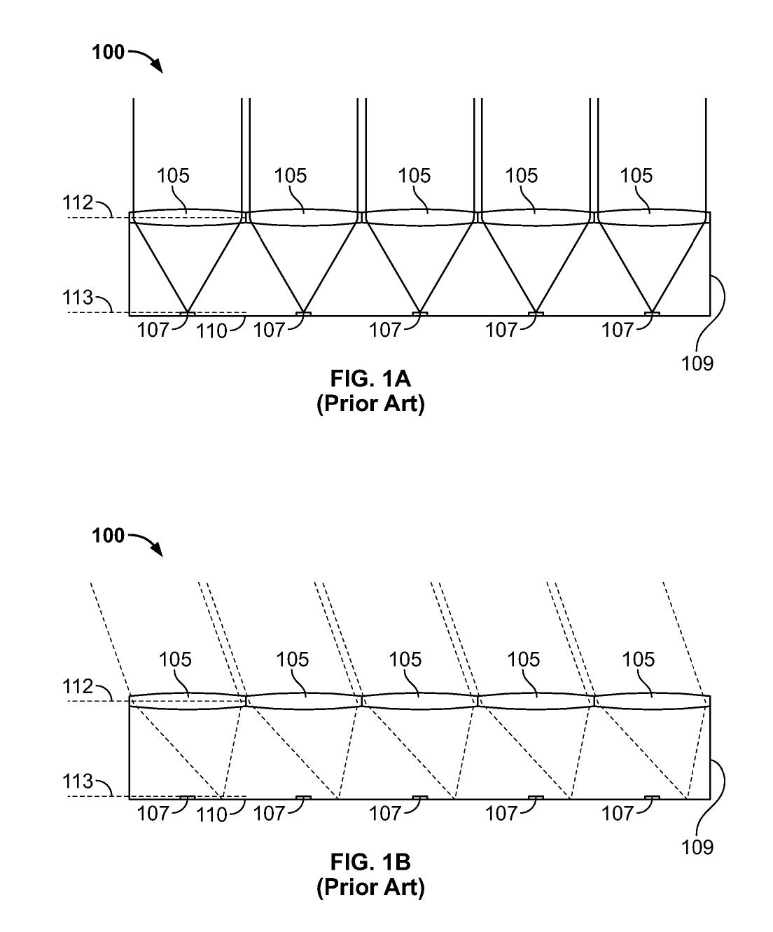

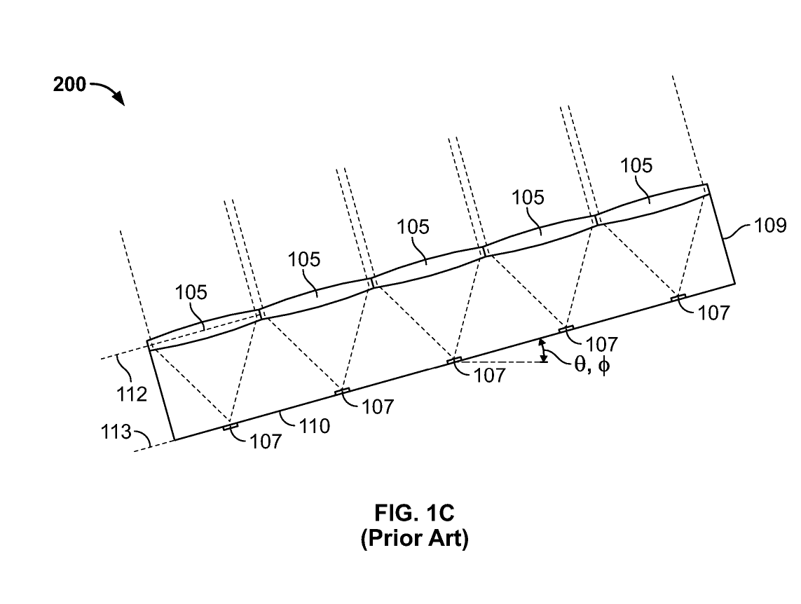

FIGS. 1A-10E show a light collection assembly.

FIG. 11 shows a light collection assembly incorporating corrective optics for light ray steering.

Like reference symbols in the various drawings indicate like elements.

### DETAILED DESCRIPTION OF ILLUSTRATIVE EMBODIMENTS

Assemblies and techniques are described to concentrate light rays, including artificial or naturally occurring light. One application where concentrating light rays has beneficial effects is in the context of solar energy collection. For illustrative purposes, the assemblies and techniques shall be described in the context of solar rays, however, it should be understood that the assemblies and techniques can be applied in other contexts and to other light sources. The solar energy collection application described herein is but one implementation.

To reduce the cost of manufacturing photovoltaic systems, the amount of photovoltaic material required is preferably minimized. Concentrating captured solar rays onto a photovoltaic cell is one technique for maximizing solar energy collection efficiency, as more sunlight impinges on the photovoltaic cell than would otherwise impinge on its surface area. As described above, conventional solar concentrating arrays generally require adjusting the position of a solar energy collection assembly relative to the sun to track the position of the sun. The assemblies and techniques described herein provide for light energy capture without requiring positioning or adjustment of an entire solar collection assembly throughout the course of daylight hours.

FIGS. 1A-1C represent a prior art solar energy collection system. The system 100 includes a one-dimensional array of light focusing elements 105 (such as lenses) that focus solar radiation 103. The system 100 further includes a one-dimensional array of photovoltaic elements 107 positioned at or near the focal points of each focusing element 105, as shown in FIG. 1A. The light focusing elements 105 and photovoltaic elements 107 can be housed in a structure 109 that maintains the relative position of the photovoltaic elements 107 to the light focusing elements 105, including the relative angle between the plane of the light focusing elements 105 (e.g., plane 112) and the plane of the photovoltaic elements 107 (e.g., photovoltaic surface 113). In such a conventional configuration and using conventional light focusing elements 105, the solar radiation 103 is maximally focused on the photovoltaic elements 107 when the solar rays are normally incident upon the light focusing elements 105.

FIG. 1B illustrates the loss of energy capture when light is incident upon the light focusing elements 105 at oblique angles relative to the surface plane 112 of the light focusing elements 105. The illustration shows that if the housing 109 remains stationary relative to a moving light source, the focus of the solar radiation 103 can completely miss the photovoltaic elements 107 at certain times during the day (i.e., due to the moving position of the sun). In addition to the loss of energy capture, this situation can cause damage to structures that surround the photovoltaic elements 107 in the housing, such as electrical components that cannot withstand the intense focused light and/or heat from the radiation.

Some prior art systems correct for oblique incidence angles by physically re-positioning the housing 109 and its components, while maintaining a constant relative position between the light focusing elements 105 and photovoltaic elements 107. FIG. 1C shows such a system, where the housing 109 is rotated by an angle θ (and optionally a tilt angle φ) to compensate for the incidence angle shown in FIG. 1B. The relative positions of the light focusing elements 105 and the photovoltaic elements 107 remain fixed—that is, each element (105, 107) has a partner to which they are “married,” and the relative angle between the planes of each element (i.e., planes 112 and 113) remains constant when the housing 109 is in motion.

The following describes a different approach to light energy concentration than the prior art conventional systems described above, which generally are reliant on tracking systems to capture light during the course of daylight hours. A solar concentration assembly is described including an array of light focusing elements including multiple light focusing elements arranged adjacent one another, and an array of photovoltaic devices positioned beneath the array of light focusing elements. The array of photovoltaic devices includes multiple photovoltaic devices arranged adjacent one another, where each photovoltaic device is positioned beneath a corresponding light focusing element. The assembly is configured such that at a first time of a day, solar rays are incident on a receiving surface of each light focusing element at a substantially right angle, exit an opposite surface of the light focusing element and focus on a first photovoltaic device positioned beneath the light focusing element. At a second time during the day the solar rays are incident on the receiving surface of each light focusing element at an oblique angle, exit the opposite surface of the light focusing element and focus on the photovoltaic which has been translated to a new position, or on a second photovoltaic device positioned at least partially beneath an adjacent light focusing element.

At least two different embodiments for focusing light rays incident at oblique angles on an array of light focusing elements to an array of photovoltaic elements are described herein, both of which include a periodic array of photovoltaic elements. A first embodiment involves translating an array of photovoltaic devices as positioned beneath the array of light focusing elements to capture light that is obliquely incident to the light focusing elements. This embodiment allows light to be captured by a photovoltaic element that would otherwise be focused away from, i.e., off-axis to the light focusing element optical axis. A second embodiment includes using an electro-optic layer disposed on a light focusing element to steer light rays that are obliquely incident to a surface of a light focusing element onto a photovoltaic element that is not directly beneath the light focusing element. A similar photovoltaic array can be used in this embodiment. Obliquely incident light that is focused at an angle to the optical axis of the light focusing element (i.e., the axis normal to the surface of the light focusing element) that may otherwise fall in-between two adjacent photovoltaic elements in the photovoltaic element array is focused to a photovoltaic device included in the array. That is, the electro-optic layer can be used to effect angular changes in the focusing direction, so as to steer the focused light onto, for example, the nearest photovoltaic element. These and other embodiments are described further below.

### Translating Array of Photovoltaic Devices

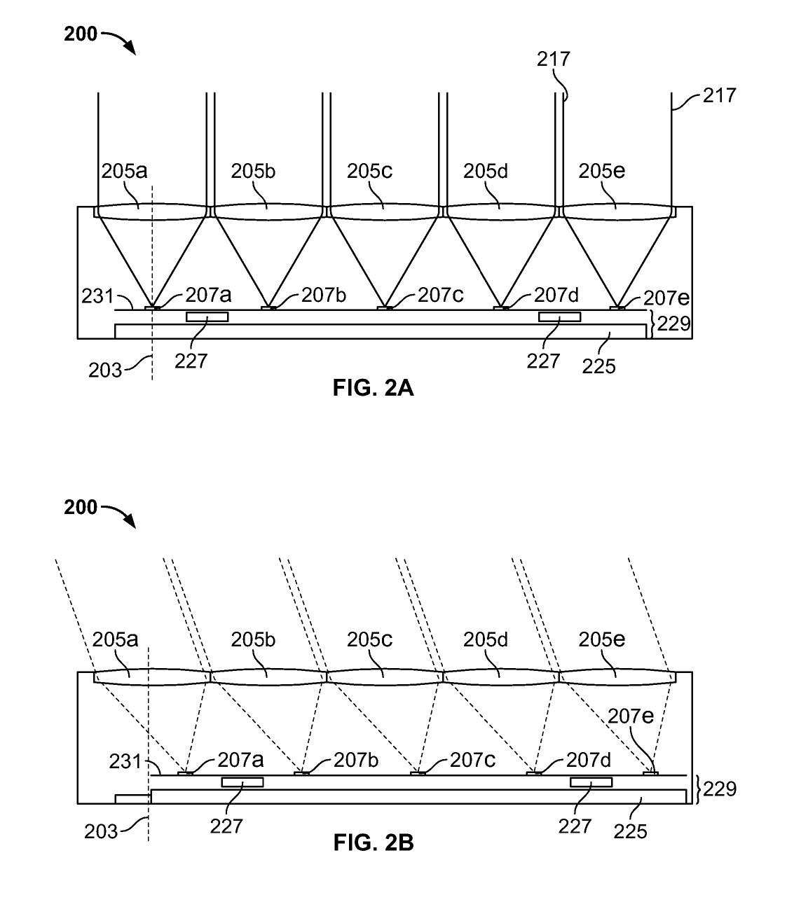

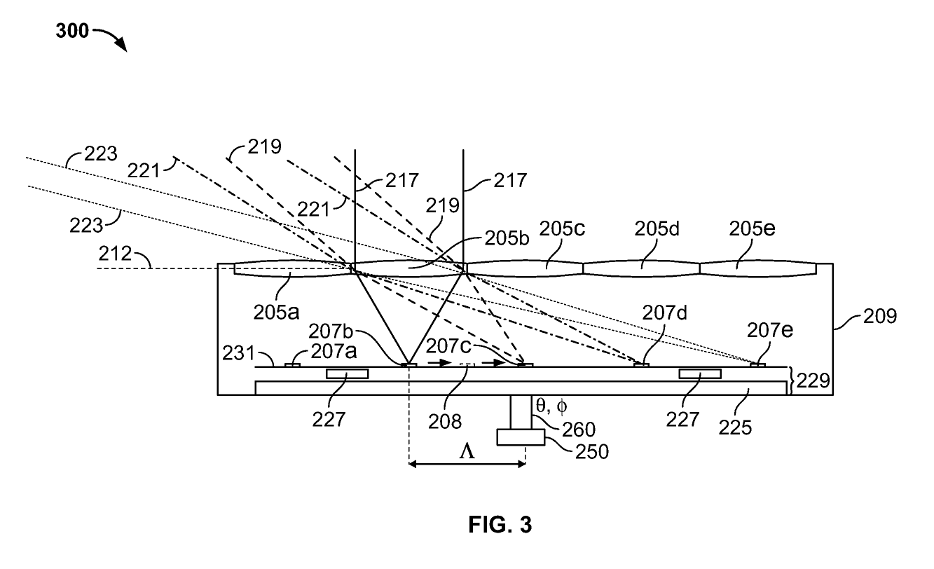

Referring to FIGS. 2A-B, one implementation of a light collection assembly 200 is shown. In this implementation, the light collection assembly 200 includes an array of light focusing elements 205a-e and an array of photovoltaic elements 207a-e arranged in linear or multi-dimensional arrays, as described further below. When light rays 217 are incident normal to the receiving surfaces of the light focusing elements 205a-e, as shown in FIG. 2A, the light is focused to impinge on corresponding photovoltaic elements 207a-e positioned beneath and substantially in axial alignment (see, dashed line 203) with the light focusing elements 205a-e. However, as the light source, e.g., the sun, moves and the light rays 217 are incident at an oblique angle to the light focusing elements 205a-e, as shown in FIG. 2B, the array of photovoltaic elements 207a-e can translate relative to the array of light focusing elements 205a-e. In this manner, as the focal point of light rays exiting the light focusing elements 205a-e moves due to the movement of the sun, the focused light rays can continue to be captured by a photovoltaic element. This is described in further detail below in relation to FIG. 3.

Referring now to FIG. 3, the path of light rays impinging on the light collection assembly 200 at different times during a day, due to movement of the light source (in this example, the sun) is shown in further detail. The light collection assembly 200 can include the light focusing elements 205a-e arranged in a linear array as shown, or a multi-dimensional array, such as an m×n array, where m and n are whole numbers (not shown). Light focusing elements 205a-e can include optical components that serve to focus light from a point source (e.g., the sun); such components are well known in the art, and can include, by way of example only, spherical and aspherical lenses, including singlets and doublets, cylindrical lenses, and Fresnel lenses. Diffractive or holographic optical elements may also be used.

An array (similarly either linear or multi-dimensional) of photovoltaic elements can be positioned such that each photovoltaic element is near a focal regions of a light focusing element(s) 205a-e, such that in a “home position” the centers of the individual photovoltaic elements are directly beneath the centers of the light focusing elements. That is, the arrays of light focusing elements 205a-e and the photovoltaic elements 207a-e are “matched.” The spacing of the photovoltaic elements 207a-e (denoted Λ in FIG. 3) can be periodic in both linear and multi-dimensional array configurations. Photovoltaic elements 207a-e can be evenly spaced in at least a first dimension (e.g., along a row of the array) but need not necessarily be evenly spaced, or spaced at the same interval as the first dimension, along a second dimension (e.g., the column spacing). In some embodiments, it may be preferable that the centers of the photovoltaic elements 207a-e are not located directly beneath the centers of the light focusing elements 205a-e in the “home position,” but rather at intermediary positions, depending on design and other factors that may influence efficiency or ease of use of the device.

A housing 209 can support both the array of light focusing elements 205a-e and the photovoltaic element array 207a-e. In some implementations, the array of photovoltaic elements 207a-e can be supported by a translatable support system 229. The translatable support system 229 shown in FIG. 3 can include a base 225 that supports a rail system 227 that further supports a photovoltaic element platform 231. The translatable support system 229 allows the array of photovoltaic elements 207a-e to be moved in unison, in response to changing incident light angle conditions and is described in greater detail below. In another implementation, the translatable support system can be configured such that each photovoltaic element can be moved independent of other photovoltaic elements in the array.

Referring to FIG. 3, consider an example wherein at noon, the sun is directly above the light collection assembly 200, and the light rays 217 are shining down upon the surface of a light focusing element 205a at normal incidence. When light is incident upon the light focusing element 205a substantially normal to its surface, i.e., parallel to the principle axis of the lens, or perpendicular to the optical center (see dashed line 212), the light rays are focused toward a corresponding (“matched”) photovoltaic element (i.e., element 207a in FIG. 3). As time progresses, the incidence angle of the light rays becomes progressively more oblique as is shown by rays 219, 221, and 223; the position of the light focusing elements 205a-e remains stationary. As this occurs, the platform 231 that supports the photovoltaic elements 207a-e can be translated in a direction such that the light rays constantly impinge on a photovoltaic element (as illustrated in FIG. 3, photovoltaic element 208 represents photovoltaic element 207 as it is translated over time).

The platform 231 can be configured to translate a maximum of one period Λ, however, a wider range of translational motion may be desirable in certain embodiments. After a period of time, the position of one photovoltaic element, e.g., element 207a, approaches the previous position of a neighboring photovoltaic element, i.e., element 207b. At this point, one implementation, the platform 231 can return to a “home” position, that is, where each photovoltaic element in the array returns to its original position beneath a corresponding light focusing element, and the light rays exiting a light focusing element, e.g., 205a, now impinge on the neighboring photovoltaic element, i.e., 207b, rather than the photovoltaic element (i.e., 207a) positioned directly beneath said light focusing element 205a. This process can be repeated multiple times as the incidence angle to the light focusing element 205a becomes increasingly oblique; after each iteration, the light can impinge on a photovoltaic element (e.g., 207b) one further away from the previous photovoltaic element (e.g., 207a) in the photovoltaic element array 207a-e. In other words, throughout the course of a day, focused sunlight from a particular light focusing element 205a can “hop” along a dimension of the photovoltaic element array 207a-e, focusing sunlight on photovoltaic elements in the order 207a, 207b, 207c, 207d, 207e, etc. The distance (i.e., the number of periods) that light can focus away from a given light focusing element 205a can be governed by the parameters and optical characteristics of the light focusing element 205a.

The entire array of photovoltaic elements 207a-e can be moved in one direction a distance Λ/2 (the halfway point between two adjacent photovoltaic elements, e.g., 207a and 207b). As the sun's position changes, the entire photovoltaic array 207a-e can then be translated back through the “home” position plus a distance −Λ/2 (i.e., in a direction opposite to the first direction). A photovoltaic element 207b adjacent to the photovoltaic element 207a that was previously receiving the light can receive the focused light from the neighboring focusing element 205a. This can continue until the light is now within the range of the second adjacent photovoltaic 207c, and so on. In this method, the photovoltaic element array 207a-e need only be translatable a distance equal to Λ/2 in either direction.

With increasing obliquity of incident light, i.e., incident light rays 221 and 223, the light focusing element 205a can ultimately focus the incident light onto photovoltaic elements increasingly further away from its matched light focusing element (i.e., photovoltaic element 207a), that is, focused toward photovoltaic elements 207c and 207d, by iterating the above described process.

While the system 200 in FIG. 3 is shown to receive light over a distance of three periods Λ, it should be understood that the system 200 can be configured to receive light over any number of period Λ distances using the same principles as described.

The system 200 can include a base 250 and one or more supports 260 affixed to the housing 209 to allow horizontal (azimuthal) and elevation (i.e., angle above the horizon) angle changes if necessary. This feature can be useful for making gross seasonal or diurnal changes in the pointing direction of the housing 209 and during installation of the system 200. For example, a user of the system 200 may utilize the base 250 and supports 260 to mount the system such that it points towards the southern sky (for a user in the northern hemisphere) at an elevation of 70 degrees above the horizon.

The sun's path follows a course relative to a terrestrial observer that depends both on the seasonal (elevation) and diurnal cycles. Similarly, the sun's path during the course of a day does not follow a straight path from the perspective of a terrestrial observer; instead the path is more similar to an arc with large azimuthal angle changes (diurnal) and smaller elevational changes. The system 200 can be configured to make the necessary beam steering adjustments to account for both variables. In certain embodiments, the photovoltaic elements 207a-e can move in the x-direction, e.g., to account for the diurnal course, and also in the y-direction, e.g., to account for coarse seasonal elevation and the finer daily elevational changes. Such embodiments that include multi-directional translation of either the photovoltaic arrays 207a-e and/or light focusing element array 205a-e are also applicable to implementations that utilize an electro-optic beam steering mechanism which is discussed below.

In one implementation, an electronic feedback system can be employed that monitors the intensity of light impinging upon a particular photovoltaic element 207a-e or averages the intensity over the array of photovoltaic elements, and controls the translatable support system 229 correspondingly to maximize the power output of the system 200. In other embodiments, photodiodes or other light-sensitive electronic components can be incorporated to monitor the brightness or flux of light at or near each photovoltaic element.

Mechanical devices that can control the position of the photovoltaic element platform 231 include, by way of example, rail systems, pulleys, gears, drive shafts, actuators, solenoids, motors, and any combination of the preceding, although other mechanisms can be used. For example, the entire support plane of the photovoltaic elements may ride upon a grid of fixed rotating spheres that allow one or more electric motors and struts to move the entire photovoltaic element grid in two-dimensional space to track the sun in both azimuth and elevation.

The platform 231 can be formed from, or covered with, a material that is optically diffuse and of high thermal conductivity, so as to reduce potential damage to system 200 components resulting from absorbing the energy of the focused beam or focused reflections.

The efficiency of many photovoltaic elements 207a-e goes down as the temperature of the absorbing medium goes up. This effect can be problematic in solar energy collection systems, as the energy absorption efficiency of photovoltaic element 207a-e materials is not 100%, and much of the energy is imparted to the surroundings as heat. Active heat-transferring methods can be used to reduce the deleterious effect of heat build-up in the system 200, by, for example, attaching water, or other fluid channels to surfaces of the platform or housing 209. In some embodiments, a cooling line (such as a copper tube) can be configured to run in-between the photovoltaic elements to provide cooling to the photovoltaic elements 207a-e and the photovoltaic element platform 231. This fluid can be optionally used in other economically- or environmentally-friendly constructs, such as providing hot water for bathing or cleaning once it has absorbed heat from the system 200. Active heat-reducing methods can generally comprise those that utilize transference of heat via a flowing, liquid heat sink, such as water.

Passive heat-reducing techniques may also be employed. These embodiments can utilize static heat sinks and other devices, such as cooling fins, or fans attached to various surfaces of the system 200, for example, the surface of the housing 209, or the photovoltaic platform 231.

Internal components of the system 200 may be particularly susceptible to damage during a time when the photovoltaic elements 207a-e return to a “home” position (e.g., at the end of a day when the sun sets) or while changing the position of the photovoltaic elements 207a-e as described above. In one implementation, the photovoltaic platform 231 can be made from, or coated with, an optically smooth surface that can dissipate the concentrated solar energy by means of specular reflection or light scattering, and are those generally referred to as Lambertian surfaces. By way of example only, the material can be a lightly colored ceramic.

The system 200 shown in FIGS. 2A-B and 3 can significantly reduce the energy required to operate the system 200 over the course of a day, as compared to a conventional solar collection assembly that requires moving significantly heavier components to track the sun. That is, advantageously a smaller mass requires movement, i.e., the photovoltaic array 207a-e which can be moved a smaller distance, i.e., perhaps only inches, over the same time period. Furthermore, the translatable platform 231 can be sealed within a housing (not shown in FIGS. 2A-B) that can protect both the mechanical and electrical elements from exposure to the weather, thus reducing maintenance cost and the operational lifetime of the system.

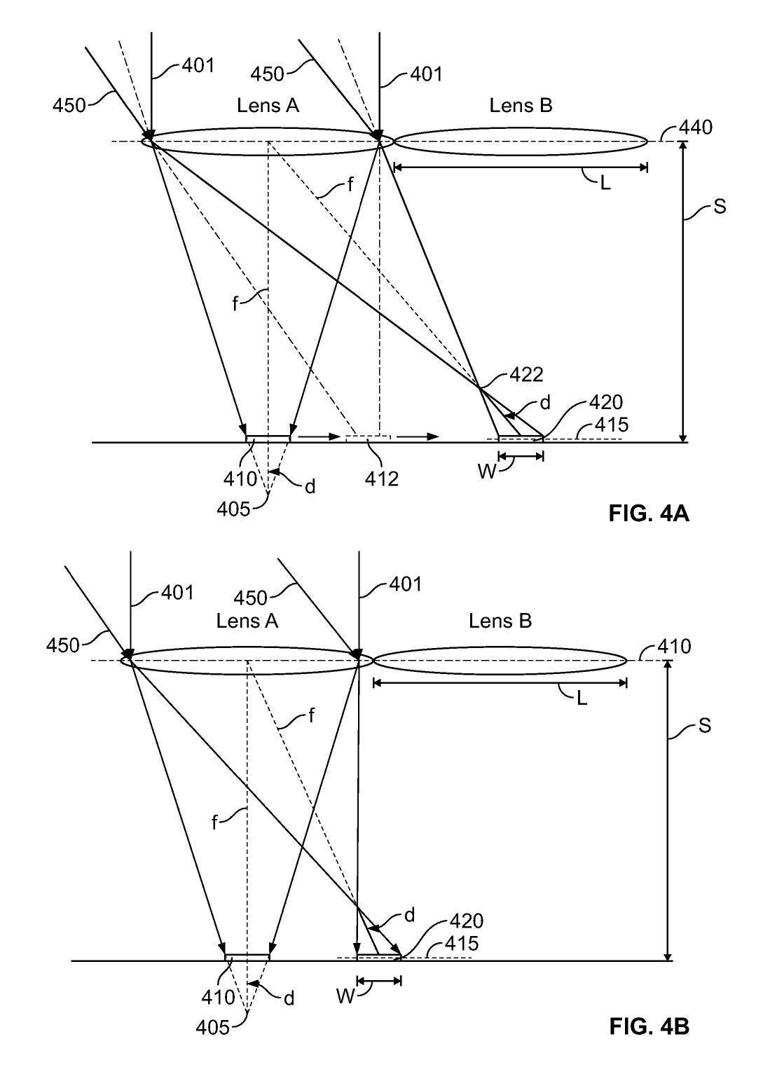

The flux of light impingent on the photovoltaic elements 207a-e can be maximized, and potential damage from intense light focusing conditions can be avoided, in the aforementioned following periodic configurations by considering certain characteristics of the system 200 components. As shown in FIG. 4A, normally incident light rays 401 can impinge perpendicularly on a Lens A and are subsequently focused toward a corresponding (i.e., “matched”) photovoltaic element 410. In certain embodiments, the photovoltaic element 410 can be positioned at a location “ahead of” the focus of the Lens A (i.e., focus point 405) to illuminate approximately the entire photovoltaic element 410 and therefore capture increased light energy. This configuration can also prevent potential damage to the photovoltaic element 410 from receiving an energy density that exceeds the damage threshold of the photovoltaic element 410, and is described below.

For illustrative purposes, in relation to the equations shown below: S is the distance between the lens plane 440 and photovoltaic planes 415; L is the diameter of the lens; w is the scale length of the photovoltaic element; f is the focal length of the lens; and d is the distance between the focal point and the photovoltaic plane.

The area of solar energy that impinges a photovoltaic element (e.g., photovoltaic element 410) can be expressed as a concentration C and is given approximately by:

$$C = {( \frac{L}{w} )}^{2} .$$

The distance d can be calculated as follows:

$$d = f ( \frac{w}{L} ) = \frac{f}{\sqrt{c}} .$$

The distance S can be calculated as follows:

$$S = f - d = f ( 1 - \frac{w}{L} ) .$$

As the light rays move from zenith (i.e., impinging normal to the surface of Lens A), the focal spot of the light from Lens A begins to move and the photovoltaic element 410 moves to follow it. At the same time, the lens-photovoltaic separation distance steadily increases and the size of the illumination spot on the photovoltaic element decreases. Once the focal spot falls precisely on a non-centered photovoltaic (as is indicated by position 412 of the photovoltaic element 410), further declination of the sun increases the spot size on the photovoltaic element to a second position of optimal illumination (i.e., the position of photovoltaic element 420). This is illustrated by the ray traces of the oblique light rays 450, which go through a focal point in empty space, and then defocus; the rays can be captured across a substantial portion of the surface of the neighboring photovoltaic element 420.

By selectively choosing the parameter L for a given C, the second position of optimal illumination can be determined. By way of example, if one chooses a second optimal illumination position directly below the adjacent light focusing element, in this example Lens B, the focal length and plane separations are given by:

$$\begin{matrix}f = ( \frac{L}{2} ) {C}^{\frac{1}{4}} ; and \\ S = ( \frac{L}{2} ) ( {C}^{\frac{1}{4}} - {C}^{- \frac{1}{4}} )\end{matrix}$$

Similarly, if, by way of example, the desire is to position the second optimal illumination position at the halfway position between two light focusing elements, in this example Lens A and Lens B as shown in FIG. 4B, these parameters are given by:

$$\begin{matrix}f = ( \frac{L}{4} ) {C}^{\frac{1}{4}} ; and \\ S = ( \frac{L}{4} ) ( {C}^{\frac{1}{4}} - {C}^{- \frac{1}{4}} )\end{matrix}$$

The second optimal illumination position can be generalized from the above formulas to any position between adjacent photovoltaic elements, by replacing the L/4 term in the above formulae with L/x, where x is half the distance between the centered photovoltaic elements, i.e., photovoltaic element 410 and photovoltaic element 420. The second optimal illumination position can be selected to take advantage of the best performance of the periodic photovoltaic elements when exposed to maximum solar illumination. Once the sun angle surpasses the second peak position, the light rays impinging on a photovoltaic element constantly decrease proportional to the cosine of the sun's incident angle.

In some implementations, further optimization of the quality of focus on the photovoltaic elements can be achieved by using concentrator lenses with improved off-axis performance. Such lenses or lens systems are commonly known as scan lenses and translate the angular displacement of an input beam into a linear translation of a focused spot, where for well-corrected systems the focused spot substantially remains within a given focal plane for a wide range of angles of incidence.

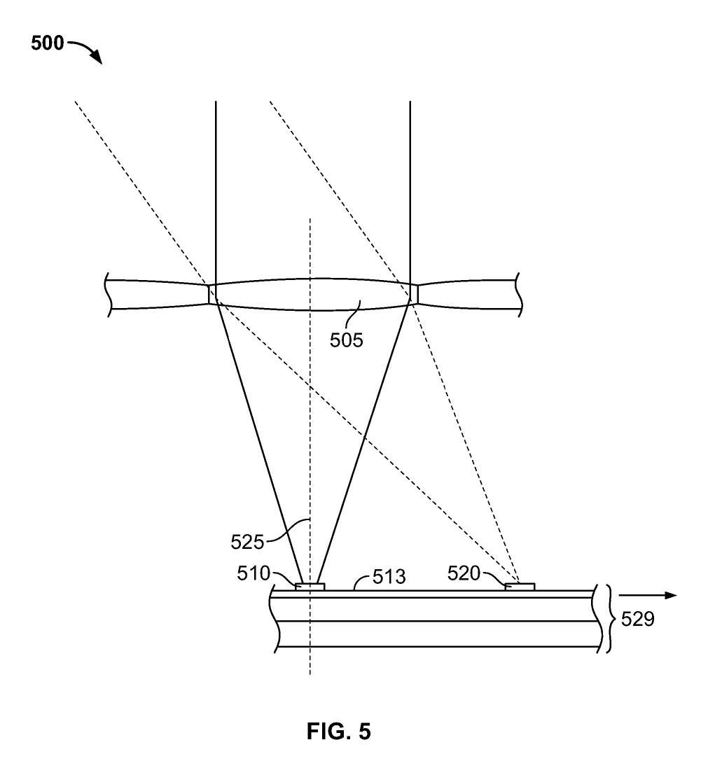

As mentioned above, a photovoltaic element can be exposed to high energy densities if the light focusing element and the photovoltaic element are arranged such that the photovoltaic element translates through the focus of the light focusing element. The energy density may be so great that it causes damage to the absorbing material of the photovoltaic element 410 and/or the photovoltaic element platform (e.g., photovoltaic platform 231). Such a situation is undesirable, as it may require replacement of expensive photovoltaic elements or other components, and can reduce the efficiency of the photovoltaic element 410. FIG. 5 shows two photovoltaic elements, 510 and 520, which can be two photovoltaic elements in an array of photovoltaic elements, i.e., 510 and 520 and represents a single period within the array. As the photovoltaic platform 513 is translated away from the home position (as illustrated by the dashed line 525 that shows the centers of photovoltaic element 510 and light focusing element 505 aligned), the distance between the light focusing element 505 and the photovoltaic elements 510 increases, and the light energy may be brought to a much tighter focus on a photovoltaic element 510, e.g., as shown for the photovoltaic element at position 520. This can be a problem, as the highly concentrated light energy may not be as efficiently converted to electrical energy and/or can cause physical damage to the photovoltaic element 510 and/or platform 513 as described.

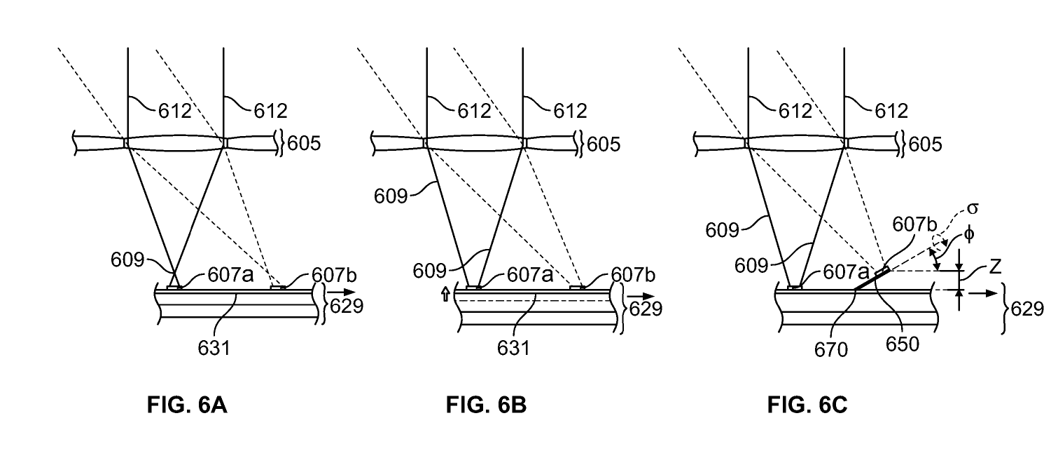

In some implementations, one or more solutions to the aforementioned problem can be integrated into a configuration of a light collection assembly as described further below in reference to FIGS. 6A-C. Referring particularly to FIG. 6A, in one implementation, the aforementioned problems encountered when translating a photovoltaic element 607 through a focal point of a light focusing element 605 can be mitigated by intentionally bringing the light to a focus (as indicated by numeral 609) less than the distance between the light focusing element 605 and the photovoltaic element 607. Thus, as the sun tracks across the sky, the light concentration may be kept from increasing to levels which may cause degraded performance or damage to the system.

In another embodiment shown in FIG. 6B, the entire photovoltaic array 607a-b can be moved closer to the light focusing element 605 when solar energy is incident at oblique angles, thus reducing mechanical complexity and the number of moving parts. By way of example, displacement of the photovoltaic elements 607a-b can be provided actively through the use of electrical motors, or passively through the use of mechanical cams or ramps 629 that can raise or lower the photovoltaic devices, either individually or as an entire array, as the photovoltaic platform 631 is moved. When the photovoltaic element 607 is in its “home” position (i.e., beneath its corresponding light focusing element 605), the light rays 612 do not come to a focus prior to reaching the photovoltaic element 607. As the platform 631 translates away from the home position, the photovoltaic element 607 travels less than the effective focal length of the lens for the obliquely incident light and therefore does not travel through its focus. Certain embodiments may include coarse displacement of the photovoltaic elements and/or the system housing (e.g. housing 209 in FIG. 3) to correct the effects due to one or both of daily and/or annual tracking.

Referring to FIG. 6C, in another implementation, the photovoltaic elements can be mounted to arms 650, such as cantilever arms, that can rotate about a point 670. As photon absorption losses may occur for light that impinges obliquely upon a receiving surface of the photovoltaic element 607, it can be desirable to position the receiving surface such that light rays focused from an oblique incidence angle onto the light focusing element 605 impinge the receiving surface at a substantially normal incidence angle. The arms 650 can be repositioned by a cantilever action as shown in FIG. 6C (i.e., the angle Φ) as well as a tilt angle σ to both keep the level of solar energy concentration mostly constant and help reduce additional losses due to obliquity (cosine) effects as the sun tracks across the sky.

FIG. 6C shows one embodiment that utilizes multiple degrees of freedom with respect to the position and orientation of a photovoltaic element, e.g., photovoltaic element 607b. In some situations, it can be beneficial to provide the ability to raise the entire photovoltaic element array platform 631, e.g., to minimize damage effects as was described above, while also re-positioning a photovoltaic element, e.g., photovoltaic element 607b, to maximize light exposure from the light focusing element 605. Furthermore, the photovoltaic element 607b can be rotated about a rotation axis σ (as shown in FIG. 6C) that can allow re-positioning of the surface of the photovoltaic element 607b such that it is directly facing the light focusing element 605. Rotation axis σ can rotate around the cantilever arm, for example.

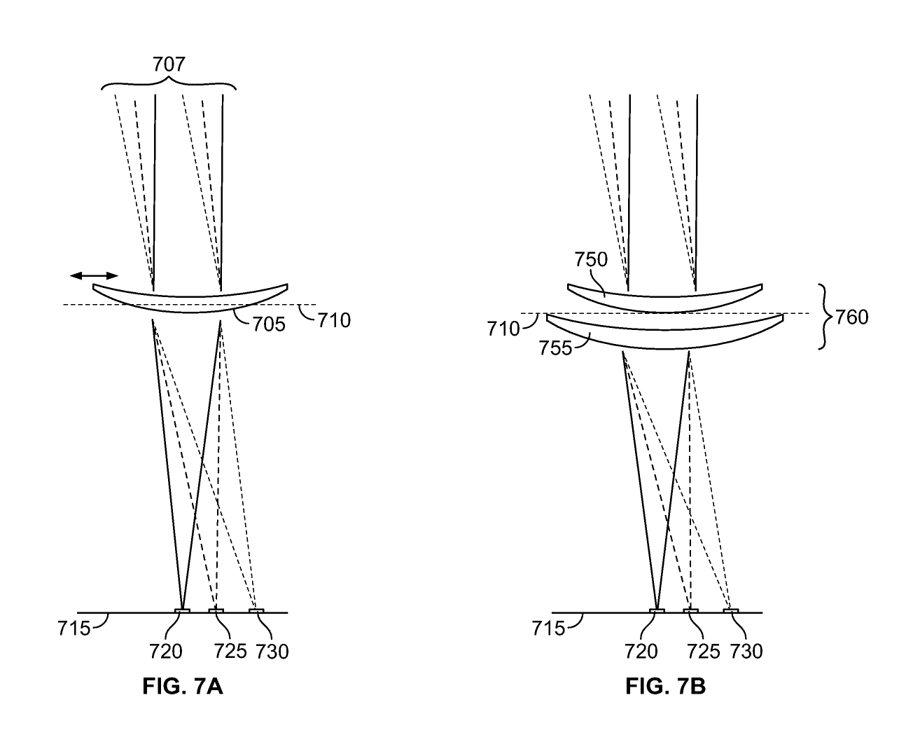

In some implementations, the light focusing elements can be selected so as to improve off-axis performance. In one example, the light focusing elements are scan, or f-theta lenses, which translate an angular rotation of incident light rays into a linear shift of the focal point within (ideally) the same plane 715 as shown in FIGS. 7A and 7B. For example, referring to FIG. 7A, an f-theta lens 705 can be constructed from single lens elements in which they comprise a positive optical power meniscus lens. FIG. 7A shows an f-theta lens 705 with light 707 incident from several different angles as indicated by the different style lines. For a given angle, the lens 705 can be in a position to focus light 707 to a photovoltaic element generally depicted at position 720. As time progresses, for example, as the sun moves across the sky, the lens 705 translates the angular shift of rays into a linear shift of the focal point within focal plane 715, which re-positions the focus of the light to different positions, for example, the positions indicated by positions 720 and 725.

An f-theta lens can be used to correct for off-axis focusing in any of the implementations disclosed herein and with other embodiments of this disclosure. The f-theta lens 705 can be integrated into a moveable platform that supports the array (linear or multi-dimensional) of light focusing elements described above, such that both the light focusing element array and the photovoltaic element array are movable relative to one another.

In an alternative implementation, FIG. 7B shows a system of lens elements (lenses 750 and 755) with different optical powers, that together comprise the f-theta lens 760. Similar to FIG. 7A, the f-theta lens 760 can create focused spots for off-axis incident light as is indicated by the different styled lines, focusing the light to a photovoltaic element 720 when it is directly below the f-theta lens 760, or when the light is incident at oblique angles (photovoltaic element at positions 725 and 730). While the single element system represents the simplest system with the least degrees of freedom for optimization of overall lens system performance, increasing the number of elements to increase the degrees of freedom for optimization can come at the cost of reduced transmission due to Fresnel losses from the additional optical surfaces.

### Electro-Optic Light Ray Steering Assembly

In certain embodiments of the light collection assemblies and systems disclosed herein, an electro-optic layer can be present on a surface of the light focusing element (e.g., light focusing element 605). The electro-optic layer can be constructed and incorporated as part of the light focusing element to steer incident light rays by controlling the refractive index of the electro-optic layer, as is discussed in detail below. The combination of an all-optical lens (e.g., a spherical singlet lens, or a Fresnel lens) and an electro-optic light ray steering layer can result in a focusing system that is precisely tunable over wide incident angle ranges and is adaptable to many configurations.

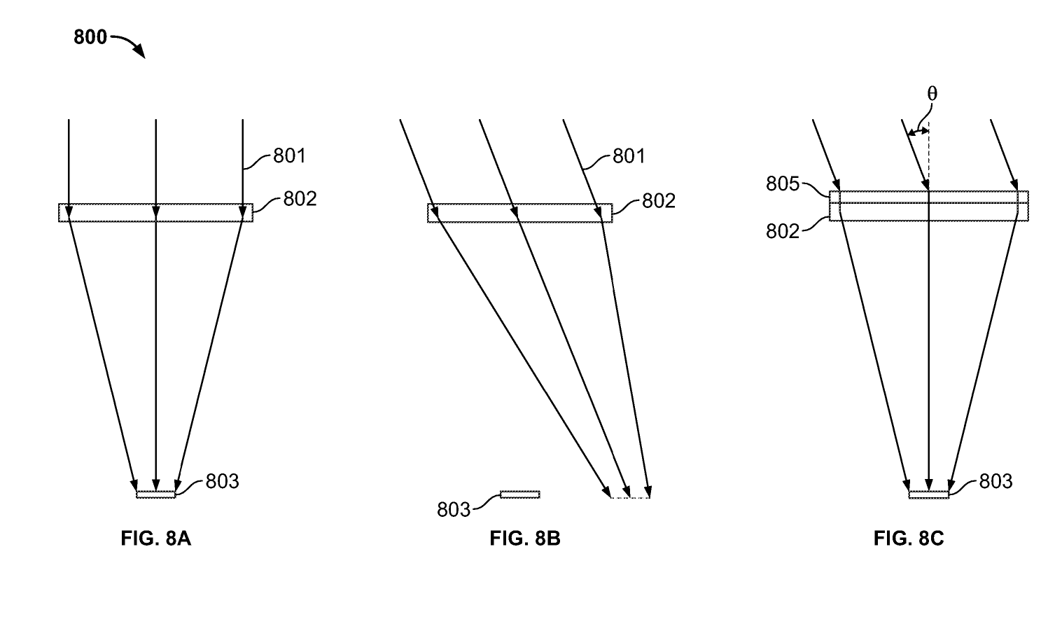

The major components of a light concentration assembly 800 that uses transmissive lenses are shown in FIG. 8A. The sun's rays 801 can impinge orthogonally onto a light focusing element 802 where they become focused on a photovoltaic element 803. If the sun's rays do not impinge on the lens orthogonally, the sunlight is not focused onto the photovoltaic, as shown in FIG. 8B, and energy can be potentially lost.

Referring to FIG. 8C, by using an electro-optic steering layer 805 positioned over the lens 802, the sun's rays falling within an angle ±θ from zenith can be steered orthogonal to a receiving surface of the lens 802, maintaining the proper sunlight focal region on the photovoltaic element 803. The angle θ is the maximum steering angle of the electro-optic steering layer 805. However, once the incident angle of the sun's rays exceeds the angle θ, the focused sunlight can again miss the photovoltaic element 803, as in FIG. 8B, and is potentially lost.

Advantageously, the total angular range of the electro-optic steering layer and its associated light focusing element can be extended by employing the phased-array type system architecture described above. The sun's rays from a given light focusing element are permitted to impinge upon neighboring photovoltaic elements, and not just the photovoltaic element located directly beneath the light focusing element.

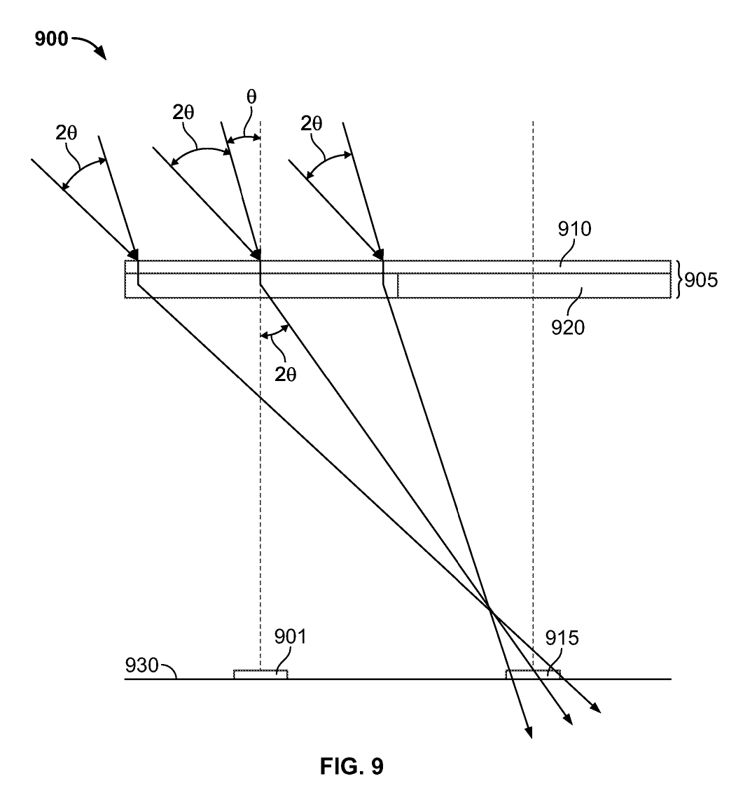

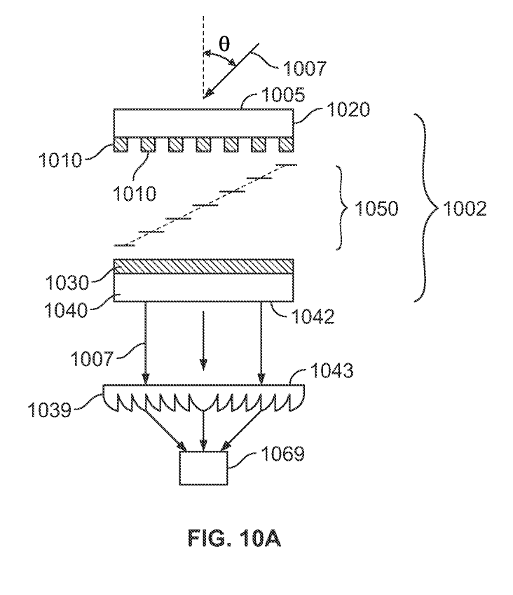

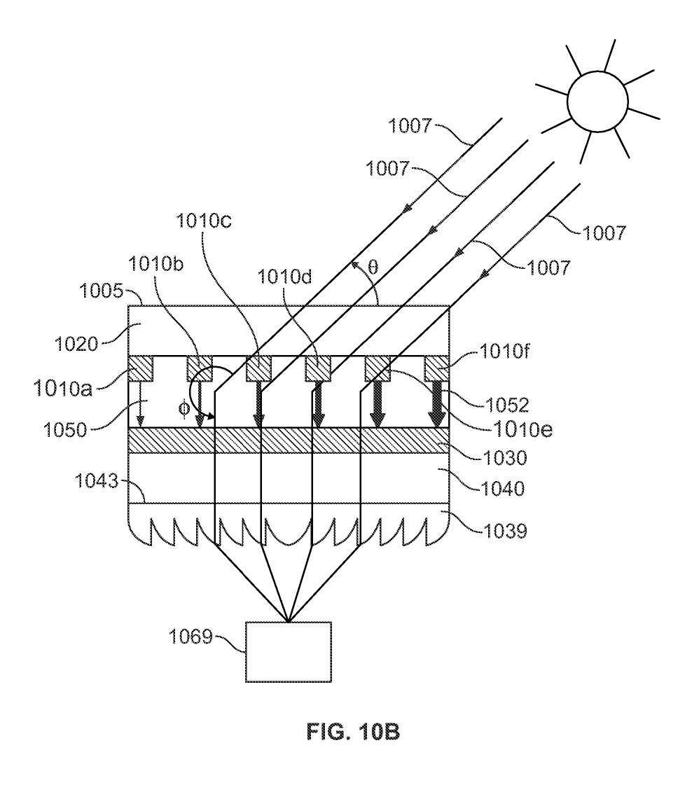

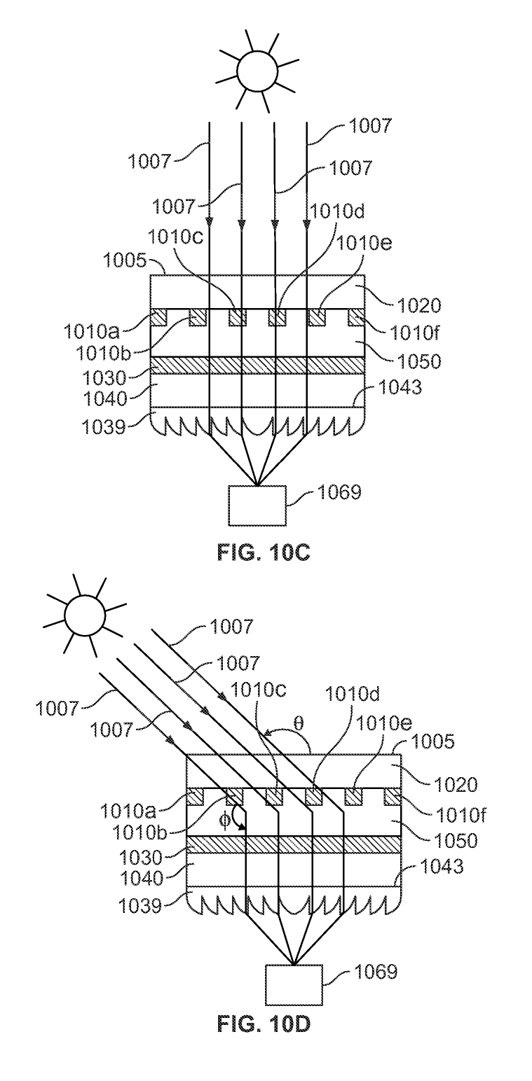

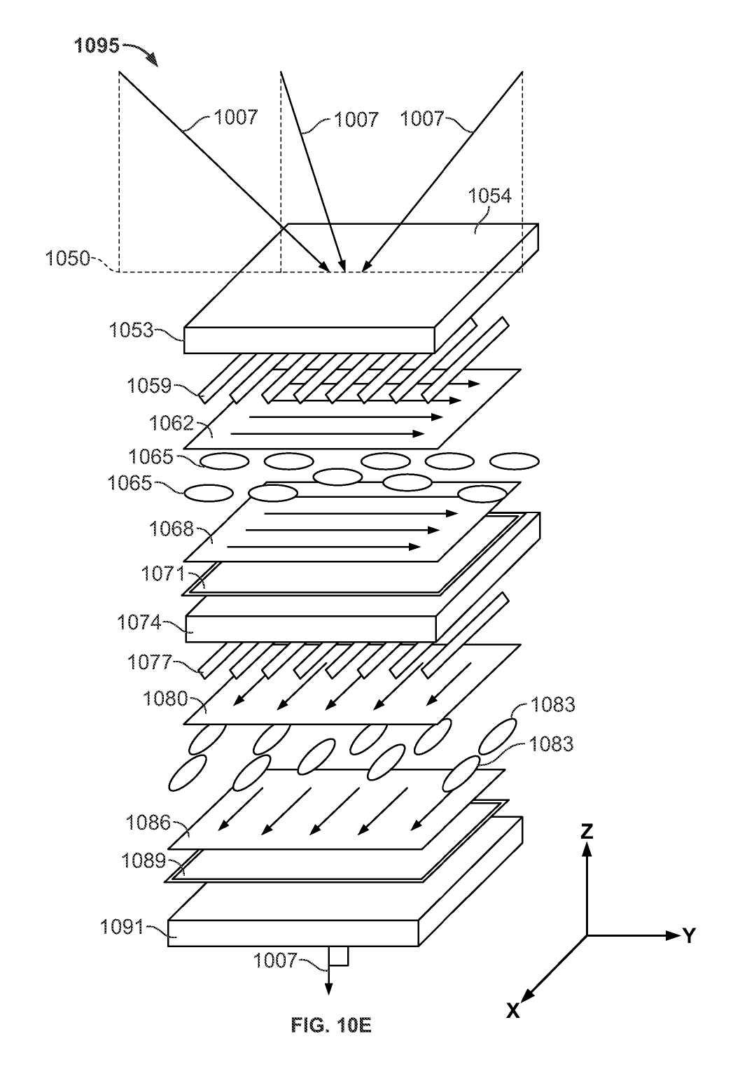

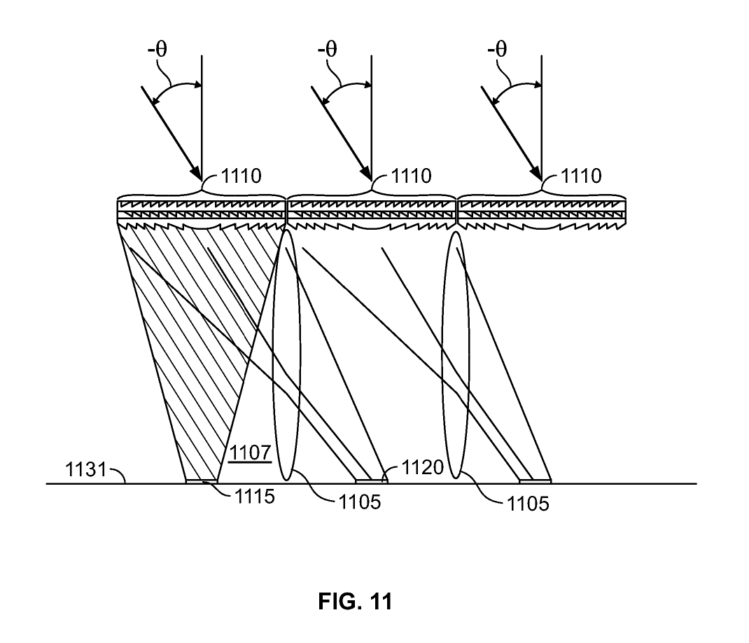

Referring now to FIG. 9, when the incident angle of light rays exceeds the angle θ on a given light focusing element 905, the light rays may not be able to be steered to the photovoltaic cell 901 directly below, i.e., the angle of incidence is outside of the −θ to +θ angular range. The light focusing element 905 includes the electro-optic steering layer 910 and a lens 920. However, if photovoltaic elements 901 and 915 are positioned a distance corresponding to 2θ apart on the photovoltaic platform 930, the focused light rays can impinge on an adjacent photovoltaic cell 915 when the electro-optic steering layer is turned off (i.e., not steering) and the sun's angle is 2θ from the zenith.

Since the electro-optic layer can still steer the sun's rays through ±θ at the 2θ position, the steering unit 905 can direct incident light to an adjacent photovoltaic element for sun angles from +θ to +3θ. This is referred to as the 1^{st}-order mode. By extension, it is apparent that incidence angles of −θ to −3θ can also be steered to the adjacent photovoltaic element in the reverse direction, extending the total angular coverage from −3θ to +3θ measured from zenith in the 0^{th}- and 1^{st}-order modes.

Continuing to exploit the above described technique, it is apparent that electro-optic steering to the 2^{nd}-order mode, namely the 2^{nd} adjacent photovoltaic element away from light focusing element 905 is possible, adding additional angular range from ±3θ to ±5θ. Thus, if, for example, the maximum angular range of the electro-optic steering layer 910 is ±10°, sun steering from +50° to −50° can be possible by utilizing the 0^{th}, 1^{st}, and 2^{nd} order modes.

It should be noted that the efficiency of light ray steering to higher order modes may not be as high as the 0^{th}-order, due to the oblique angle of incidence of the focused light rays onto the photovoltaic elements. In one implementation, the concentrating lens 920 can be configured such that its focal spot just covers the entire receiving surface of the photovoltaic element positioned directly beneath the lens 920. Other techniques for adjusting the focal spot onto the photovoltaic elements as described earlier, such as moving the PV plane vertically to maintain focal spot size on adjacent PV elements, are possible with electro-optically steered arrays.

FIGS. 10A-E show one example implementation of an electro-optic steering layer that can be included in the light focusing element 905 described above. Other configurations of electro-optic steering layers are possible, and the one described is but one example. Referring particularly to FIG. 10A, the electro-optic steering layer is implemented as an electro-optic prism 1002. The electro-optic prism 1002 includes multiple, individual electrodes 1010 on a first substrate 1020 and a reference electrode (e.g., a ground electrode) 1030 on a second substrate 1040. An electro-optic material 1050 of substantially uniform thickness is positioned between the electrodes 1010 and 1030. In one implementation, the electro-optic material 1050 can be liquid crystal. In one implementation, the electrodes 1010 and 1030 are transparent electrodes, for example, formed of indium tin oxide.

Applying voltages to the electrodes 1010 generates an electric field in the electro-optic material 1050, causing molecules therein to rotate in the direction of the applied electric field. In some implementations, the reference electrode 1030 is electrical ground. By controlling the voltages to the individual electrodes 1010, a gradient in the refractive index (“index gradient”) of the electro-optic material 1050 can be created. The index gradient is controlled in accordance with the angle of incident solar rays 1007, which can be in accordance with the position of the sun relative to the surface 1005 of substrate 1020. As the sun moves, i.e., as the angle θ in FIG. 10A changes, the index gradient can be controllably modified, such that the incident solar rays 1007 are steered from their angle of incidence θ so as to exit the bottom surface 1042 of the substrate 1040 substantially normal to a receiving surface 1043 of the lens 1039. The solar rays 1007 are therefore incident at an approximate 90° angle on the receiving surface 1043 and can thereby properly focused toward the photovoltaic element 1069.

FIGS. 10B-D illustrate the electro-optic prism steering light rays 1007 throughout the course of a day. Light rays 1007 can be steered such that they impinge on the lens 1039 substantially normal to the receiving surface 1043, so that the solar rays 1007 can be substantially focused to the photovoltaic element 1069. In FIG. 10B, the light rays 1007 impinge on a receiving surface 1005 of a first transparent substrate 1020 at an angle θ with respect to the receiving surface 1005 of the first substrate 1020. In FIGS. 10B-D, the axis of angle θ is at the intersection of the light ray 1007 and the receiving surface 1005 of the substrate 1020; θ=0° when the light ray 1007 is parallel with the receiving surface 1005 and increases to the incidence angle of the light ray 1007 when the light ray 1007 impinges non-parallel, as indicated in FIG. 10B. Such is the situation, for example, when the sun rises from the east, from the perspective of a stationary viewer in the northern hemisphere of the earth, looking south. A series of linear, patterned, transparent electrode strips 1010a, 1101b, 1010c, 1010d, 1010e, and 1110f can be formed on the substrate 1020, such that the long axes of the electrodes are substantially parallel. An electric field can be applied to an electro-optic material 1050 by applying voltages to the electrodes 1010a-f, wherein the reference electrode 1030, formed on the substrate 1040, is electrical ground.

An index gradient can be created in the electro-optic material 1050 that bends the light rays 1007 an angle Φ as shown in FIGS. 10B-D, by applying successively increasing or decreasing voltages to electrodes 1010a, 1010b, 1010c, 1010d, 1010e, and 1010f. The order of increasing or decreasing voltage applied to electrodes 1010a-f can depend on the incidence angle of the light rays 1007, and how much refraction is necessary to bend the light rays 1007 to their target (i.e., the photovoltaic element 1069). In FIG. 10B, the order of increasing voltage applied to the electrodes 1010a-f can increase in the order: 1010a, 1010b, 1110 c, 1010d, 1010e, and 1110f for the incidence angle shown. In this implementation, the spatial gradient in index of refraction created in the material 1050 is controllable from one side of the electro-optic material 1050 (e.g., near electrode 1010a) to the other (e.g., near electrode 1010f), due to the electric fields created between each of the electrodes 1010a-f and the reference electrode 1030.

The electric field gradient (and therefore the index gradient) is exemplified in FIG. 10B as arrows 1052 between the electrodes 1010a-f and the reference electrode 1030. In this example, the strength of the electric field is indicated by the width of the arrow, where larger arrows indicate higher electric field. The magnitude of the electric field at each location (each arrow 1052) can be governed by the voltage applied to electrodes 1010a-f. The electro-optic prism 1002 in FIG. 10A is the electro-optical analog of a conventional (e.g. triangular glass or other optical material) prism. The light rays 1007 encountering the index gradient at an angle θ are refracted at an angle Φ as shown in FIG. 10B; the magnitude of the index gradient can be controlled via the applied voltages to the electrodes 1010a-f, such that the light rays 1007 impinge substantially normal on the surface of lens 1039.

As the sun moves to a position substantially normal to the surface of the substrate 1020 (thereby increasing the angle θ to substantially 90°), as shown in FIG. 10C, the index gradient can gradually decrease in magnitude by applying appropriate voltages to the electrodes 1010a-f. In this circumstance the light rays 1007 can propagate substantially free of angular steering, such that they impinge normal to the receiving surface 1043 of the lens 1039.

FIG. 10D illustrates the reverse process as shown in FIG. 10B, which occurs as the sun continues its course across the sky. Now, the voltages applied to electrodes 1010a-f can increase in the order: 1010f, 1010e, 1010d, 1010dc, 1010b, 1010a. This steers the light rays 1007 an angle Φ and can cause the light rays 1007 to impinge substantially normal to the receiving surface 1043 of lens 1039.

FIGS. 10B-D illustrate how the electro-optic prism 1002 can effectively capture solar radiation at a wide range of incidence angles (θ) without necessitating angular adjustment of the receiving surface 1005 of the first substrate 1020, or other optical components contained within the electro-optic prism 1002. By this virtue, an array of light focusing elements, each including an electro-optic steering layer, together with an array of photovoltaic elements, can remain stationary yet still capture solar rays, incident on the light focusing elements throughout a wide range of angles, throughout the day. By contrast, a conventional solar concentrating system requires a tracking mechanism necessitating physical movement of system components.

Liquid crystal molecules have a long axis (usually substantially parallel to a polar axis, if present) that may be set in a selected orientation, i.e., the orientation that the liquid crystal molecules will assume under zero applied electric field, by “brushing” one or more alignment layers (for example, a layer of polyamide). Applying an alignment layer aligns the long axes of the liquid crystal molecules near the adjoining surfaces of the liquid crystal layer (i.e., top and bottom of the liquid crystal layer) under zero external field conditions, and subsequently aligns the liquid crystal molecules throughout the volume of the material, defining the axes of the ordinary and extraordinary refractive indices of the liquid crystal material. This effect is well known, and causes parallel and perpendicular polarization components (with respect to the long (or polar) axis of the molecules) of light that travels through the liquid crystal layer to experience different refractive indices. In the absence of an applied electric field, light traveling through the liquid crystal (for a given polarization) is primarily steered in a direction governed by the orientation of the liquid crystal molecules, which should be parallel with the alignment layer. Light polarized orthogonal to the liquid crystal director (generally the direction of the long axis of the liquid crystal molecules when they are aligned) experiences substantially no change in refractive index as it passes through the liquid crystal. In most cases, the preferred orientation of the director (when no field is applied) is perpendicular to the electric field, when created.

FIG. 10E shows an exploded view of one implementation of a light steering mechanism 1095 configured to steer light rays 1007 (propagating in a plane 1050) incident on a first substrate 1053. The substrate 1053 can be transparent and can have attached thereto a series of linear transparent electrode strips 1059 oriented in a selected direction, in this example, along the indicated x-axis. A top liquid crystal alignment layer 1062 is applied to the substrate 1053/electrode 1059 surface and brushed in a selected direction (in this example the y direction), which orients a layer of liquid crystal 1065 in the same direction. A second, bottom liquid crystal alignment layer 1068 is brushed in the same direction as the top liquid crystal alignment layer 1062, to ensure total and rapid liquid crystal alignment (under zero externally-applied electric field).

The electrode 1071 is supported by a second substrate 1074, which can be substantially transparent. A layer of linear electrodes 1077 similar to 1059 is attached to a lower surface of the substrate 1074. In contact with the substrate 1074/electrodes 1077 surface is a brushed liquid crystal alignment layer 1080 that can be perpendicular to the direction of the liquid crystal alignment layers 1062 and 1068. The brushed liquid crystal alignment layers 1080 and 1086 form the top and bottom layers respectively of a liquid crystal layer 1083. In this case, the direction of the liquid crystal molecules included in the liquid crystal layer 1083 is orthogonal to the liquid crystal molecules included in the liquid crystal layer 1065. A bottom electrode 1089 is supported by a transparent substrate 1091 and is in contact with the bottom liquid crystal alignment layer 1086.

The light steering mechanism 1095 shown can steer an unpolarized light ray 1007 that impinges on the surface 1054 of the substrate 1053 at an angle, such that the light ray 1007 exits the bottom substrate 1091 substantially normal, as shown. As it is illustrated in FIG. 10E, the light steering mechanism 1095 only steers light in one direction, that being orthogonal to the direction of the long axis of the electrodes 1059 and 1077. Light rays 1007 with polarization vectors orthogonal to the first liquid crystal layer 1065 pass through the layer 1065 unchanged in direction, while those with some degree of parallelism with the liquid crystal layer 1065 undergo some degree of refraction due to the index gradient. The orthogonal rays can be refracted at the second, orthogonally-aligned liquid crystal layer 1083 (with respect to the first liquid crystal layer 1065).

If the light rays 1007 impinge normal to the receiving surface 1054 of the substrate 1053, the electrodes can be turned off, and light will pass straight through, emerging normal to the bottom substrate 1091.

To allow for two-axis light ray steering, the light steering assembly 1095 can be cloned, placing one light steering assembly 1095 on top of the other, such that the direction of the long axes of the patterned electrodes 1059, 1077 in the light steering mechanism 1095 are perpendicular to the long axes of the linear electrodes included in the second light steering mechanism. As light rays are steered orthogonal to the long axes of the linear electrodes 1059, 1077, unpolarized light ray steering in any direction can be accomplished by this approach.

An embodiment of an electro-optic prism can include, for nematic liquid crystal, all or some of the elements in FIG. 10E. An embodiment of an electro-optic prism can include, for cholesteric liquid crystal, all or some of a substrate 1053, electrodes 1059, liquid crystal alignment layer 1062, liquid crystal layer 1065, liquid crystal alignment layer 1068, electrode 1071, and substrate 1074. For electro-optic prisms using cholesteric liquid crystal, a second layer of orthogonally-aligned liquid crystal is not necessary to steer light in one direction (as is shown for the light steering mechanism 1095 in FIG. 10E), but may be used in some situations, since an index gradient within a cholesteric liquid crystal layer can refract unpolarized light.

In one implementation, a solar energy collection assembly, such as that described in reference to FIGS. 10A-E above, can use a portion of the collected solar energy for providing the voltages applied to the electro-optic material 1050. Because optical switching speed is not a significant factor in solar steering applications, i.e., the speed at which the liquid crystal molecules align under the influence of the applied electric field, thicker layers of electro-optic material 1050 as compared to layers used in other applications can be desirable, as a thicker layer allows for a greater optical phase delay, making larger angular deflections possible.

The electro-optic prism described can be of either a refractive or diffractive nature, depending on its design and construction, and the implementations described may include either prism type. A difference between the two is that a refractive prism steers light using structures (e.g., electrodes) of a relatively large size compared to the wavelength of light, while diffractive structures steer light using structures of a relatively comparable size to the wavelength of light. The behavior of refractive devices can be adequately described using Snell's law, while the wave nature of light is used to describe the behavior of diffractive devices.

Referring again to FIG. 10A, an electric field is created in the electro-optic material 1050 when a voltage is applied to the electrodes 1010, and the electrode 1030 is a ground electrode. The electrodes 1010 can be linear strips of transparent conducting material. The linear electrodes 1010 can be formed using any convenient technique, for example, by photolithography, chemical etching, and the like. The ground electrode 1030 can also be a transparent electrode, and in one implementation can be similarly constructed of linear strips of conducting material, or in another implementation, can be a contiguous planar material. In the latter case, the electrodes may be formed by techniques known by those skilled in the art of making planar transparent electrodes, such as by chemical vapor deposition (CVD), sputtering, spin-coating, and the like. In one implementation, the electrodes 1010 and 1030 are formed from indium tin oxide.

When refraction of incident light rays 1007 is desired, such as that shown in FIG. 10A, it is desirable to space the linear strips of transparent electrodes 1010 a distance that minimizes diffraction of the light rays 1007. Diffractive effects become more prominent when the spacing of a gradient approaches the wavelength of incident light. In one implementation, such as that shown for FIG. 10A, the spacing of the electrodes 1010 is on the order of three to five microns apart, and the width of each electrode (e.g., each linear electrode 1059 in FIG. 10E) can be of the same scale. The length of the electrodes 1010 can extend to the boundaries of the substrate 1020. In one implementation, a length of the electrodes 1010 can be from six to thirty centimeters.

In certain implementations, a contiguous electrode, rather than strips of individual electrodes, can be used to create the index gradient in the electro-optic material. For example, a variable resistance electrode can be used, which is discussed further below. In this case, the index gradient can be formed by the potential drop from a first end to a second end when voltage is applied to the first end. The index gradient can be formed in a selected direction by applying the driving voltage to a selected end of the variable resistance electrode and grounding the other end. In this manner, sunlight from one direction can be refracted in a selected direction by applying the driving voltage to one end of the variable-resistance electrode. The end to which the driving voltage is applied is then reversed when light rays are incident from the opposite angle.

In other implementations, a variable-thickness electrode can provide the index gradient. A variable-thickness electrode will produce a potential drop from one end to which the driving voltage is applied due to its increasing thickness. The variable-thickness electrode can be placed on a solar ray-receiving surface of a substrate and is substantially transparent. A variable-thickness electrode composed of transparent conducting material can be formed on a substrate by various means known to those skilled in the art, including CVD, dipping, or sputtering. To employ an electro-optic prism to steer solar rays from their angle of incidence to a desired orientation, e.g., orthogonal to a receiving surface of a light focusing element, information about the sun's position is required. The sun's position can be used to estimate the angle of incidence, and thereby provide the electro-optic prism with an appropriate index gradient through application of an electric field. The sun's position can be tracked using any convenient technique, including programming control electronics for the electro-optic prism with pre-determined solar coordinates (i.e., elevation and azimuthal angles) and/or continuous, active tracking of the sun's position using optical detectors and associated electronics in a feedback mode.

In one implementation, the amount of solar energy collected by a photovoltaic cell can be monitored by associated circuitry; the application of the electric field to the electro-optic prism can be integrated into a feedback mechanism. The index gradient of the electro-optic prism can be continually adjusted to provide maximum energy absorption by the photovoltaic cell, based on the information provided by the photovoltaic cell monitor.

Additionally, as discussed above, the light steering assemblies and techniques described herein can be used to steer light rays emanating from a light source other than the sun. If the light source is mobile, similar techniques as described above for solar ray tracking can be employed to track movement of the light source relative to the light steering assembly.

In one implementation, the electro-optic material 1050 is liquid crystal. The index of refraction of liquid crystal can be altered to a maximum saturation depending on the applied electric field. If the liquid crystal layer then experiences a gradient in the refractive index due to a gradient in the electric field, an optical refractive or diffractive effect can occur, resulting in a modification of the phase of a light wavefront. This effect can be used to focus, steer, or correct arbitrary wavefronts, thereby correcting for aberrations due to light propagation through the material. In this sense, liquid crystal cells configured as shown in FIG. 10A can be referred to as electro-optic prisms, since they effectively steer light a given amount proportional to an induced index gradient provided by an external voltage.

Prismatic power is generally a measurement of the magnitude of the refraction or diffraction angle that a light ray undergoes by passing through (or diffracting in) a prism. In most cases, light undergoes a higher degree of refraction (more prismatic power) for prisms formed of materials of high dispersion, i.e., large change in refractive index with wavelength.

As discussed, liquid crystals are generally elongated molecules that tend to align axially with one another along their longitudinal axis. This property of liquid crystals can be used to define a bulk direction of alignment in a liquid crystal device. The direction of the local molecular alignment is referred to as a director as described above. Due to these alignment properties, nematic liquid crystal is a birefringent material, and to steer unpolarized light, such as sunlight, two liquid crystal layers having orthogonally arranged alignment directions are typically used. That is, the direction of alignment of the liquid crystal layer in one electro-optic prism is at approximately a 90° angle to the director of the second liquid crystal layer in the second electro-optic prism when no power is applied, as shown in FIG. 10E. By way of example only, a suitable liquid crystal is BL037, available from Merck Co., Germany.

To provide the largest possible range of refractive angles, liquid crystals that exhibit relatively large differences in refractive index between zero electric field and that at saturation (i.e., they are highly birefringent) can be used, and should display low chromatic dispersion. For example, a preferred range of the change in index of refraction provided by a liquid crystal layer can be from approximately 0.3 to 0.4. BL037 liquid crystal has an effective range in refractive index of 0.28.

In one implementation, a cholesteric liquid crystal material can be used in an electro-optic prism. Cholesteric liquid crystal exhibits chirality, and the director is not fixed in a single plane, but can rotate upon translation through the material. In certain configurations a cholesteric liquid crystal layer can be substantially polarization insensitive. Accordingly, an electro-optic prism including a single layer of cholesteric liquid crystal can be used to steer unpolarized light with high efficiency. Reducing the number of layers of liquid crystal can reduce undesirable transmission loss. A stronger electric field, hence higher voltages, can be required to rotate the molecules of a cholesteric liquid crystal as compared to a nematic liquid crystal. However, since a single layer is capable of affecting both light polarizations of the solar rays, using cholesteric liquid crystal can still improve efficiency.

In another implementation, bistable liquid crystal can be used. The director of a bistable liquid crystal has two or more orientations that can be induced by application of an electric field and that remain (i.e. they are stable) after the field is removed. The result of bistable states is that when the electrical power is turned off, the prismatic effect remains, thereby minimizing the amount of electrical energy needed for the electro-optic prism.

For example, a certain voltage can be required to align liquid crystal molecules in an electric field according to their dipole moment. When that voltage is applied to a bi-stable liquid crystal, the liquid crystal molecules rotate in the field; at that point, the voltage can be turned off and the liquid crystal molecules retain their orientation. This has the benefit of reducing the energy required to keep the liquid crystal molecules in a particular orientation to affect a given steering of incoming light rays. This configuration can be particularly useful in a situation where the movement of the point light source is relatively minor, such as points on the earth near to either geographic pole. By way of example only, bistable liquid crystals can include surface stabilized ferroelectric liquid crystals (SSF liquid crystal).

### Alternative Light Collection System Configuration

A Fresnel lens can focus non-coherent light (i.e., scattered or diffuse light) to a point or plane using far less space than a typical optical lens, such as a plano-convex lens. In certain embodiments of the light collection assemblies and systems described above, it can be advantageous to use a Fresnel lens as a corrective optical component. Referring to FIG. 11, a corrective optic (e.g., a Fresnel lens) 1105 can be placed in a void 1107 between a light focusing element 1110 and a photovoltaic element 1115 (in one dimension) and between adjacent photovoltaic elements 1115, 1120 (in the other dimension). If properly configured and positioned, the Fresnel lens 1105 can increase the amount of 1^{st} order light striking the photovoltaic element 1120, without compromising the quality of the 0^{th}-order mode, where otherwise, light may not impinge on the photovoltaic element 1120. The “void” can be considered the space outside the cone of the light as it is being focused from the light focusing element 1110 to the photovoltaic element 1115 in a 0^{th}-order mode configuration. This embodiment is not limited to Fresnel lenses as the corrective optical component 1105, and, in fact, many common optical components known to those skilled in the art of optics can be used for this purpose, such as optical wedges and the like.

A focal correction may be necessary in circumstances where the focusing abilities of a given light focusing element 1110 are being pushed to its limits, such as when the incidence angle of the incoming light is extremely oblique. The efficiency of energy conversion with higher-order photovoltaic cells (i.e., when light is being focused to an adjacent photovoltaic element 1120) can be improved using this technique because less light may be lost due to focusing aberrations. The corrective optic 1105 can constitute not only a focusing element to decrease the effective area of the focal spot, but can also add structural integrity to the assembly 1100. In some embodiments, the corrective optic 1105 can attach the platform 1131 that holds the photovoltaic elements 1115, 1120 to the light focusing element array 1110.

A number of implementations have been described. Nevertheless, it will be understood that various modifications can be made without departing from the spirit and scope of the disclosure. For example, the devices enabled can be placed on crafts that exit the Earth's atmosphere, such as the Space Shuttle, or Space Station. The light-absorbing medium of the photovoltaic elements can include silicon, semiconductors, as are known in the art, or other variants, to include nano-crystals, nano-tubes, and the like. In some embodiments, the local insulation data may be used to determine how the systems and assemblies disclosed herein, including the photovoltaic positioning, are designed to maximize the photon collection capability. Accordingly, other implementations are within the scope of the following claims.

What is claimed is:

1. A solar concentration assembly comprising:
an array of light focusing elements comprising a plurality of light focusing elements arranged near one another; and
an array of photovoltaic devices positioned beneath the array of light focusing elements, comprising a plurality of photovoltaic devices arranged near one another;
wherein the arrays of light focusing elements and photovoltaic devices are spaced from one another and configured to concentrate solar rays incident on the light focusing elements to the photovoltaic elements such that solar ray communication is maintained as an angle of the assembly relative to the sun is altered by movement of the sun during a day and wherein the angle comprises an oblique angle for the majority of the day.

2. The assembly of claim 1, wherein maintaining optical communication is effected using an electro-optic layer included in the light focusing elements.

3. The assembly of claim 1, wherein maintaining optical communication is effected by relative translational movement between the array of light focusing elements and the array of photovoltaic elements.

4. The assembly of claim 1, wherein the spacing between the array of light focusing elements and the array of photovoltaic devices is adjustable.

5. The assembly of claim 1, wherein at least one of the arrays is configured to move in two dimensions within a plane of the array.

6. The assembly of claim 5, wherein the at least one array is configured to move in a first dimension to compensate for movement of the sun during a day and to move in a second direction to compensate for seasonal movement of the sun.

7. The assembly of claim 1, wherein each array is positioned in a plane and each array is adjustable by intra-plane and inter-plane movement.

8. The assembly of claim 1, wherein the array of light focusing elements and the array of photovoltaic devices are both two-dimensional arrays including m elements in a first direction and n elements in a second direction, where m and n are whole numbers.

9. The assembly of claim 1, wherein the array of light focusing elements is stationary with respect to a terrestrial surface.

10. The assembly of claim 1, wherein the array of photovoltaic devices is stationary with respect to a terrestrial surface.

11. The assembly of claim 1, wherein the array of light focusing elements includes one or more Fresnel lenses.

12. The assembly of claim 1, wherein the array of light focusing elements includes one or more f-theta lenses.

13. The assembly of claim 1, wherein the assembly is configured such that at a first time of the day solar rays are incident on a receiving surface of a light focusing element at a substantially right angle, exit an opposite surface of the light focusing element and concentrate on a first photovoltaic device in a first position beneath the light focusing element and at a second time during the day the solar rays are incident on the receiving surface of the light focusing element at an oblique angle, exit the opposite surface of the light focusing element and concentrate on a second photovoltaic device at a second, different position.

14. The assembly of claim 13, wherein at a third time during the day the solar rays are incident on the receiving surface of the light focusing element at an oblique angle, exit the opposite surface of the light focusing element and concentrate on a third photovoltaic device at a third, different position.

15. The assembly of claim 1, further comprising:
a translation mechanism configured to translate the array of photovoltaic devices relative to the array of light focusing elements.

16. The assembly of claim 15, wherein each photovoltaic device has a home position and a maximum translation position and wherein the translation mechanism is configured to translate the photovoltaic devices from the home position to the maximum translation position and return the photovoltaic devices to the home position.

17. The assembly of claim 16, wherein the home position is a position such that the photovoltaic device is substantially axially aligned with a light focusing element positioned above the photovoltaic device and the maximum translation position is a position approaching the home position of an adjacent photovoltaic device.

18. The assembly of claim 16, wherein the home position is a position such that the photovoltaic device is substantially axially aligned with a light focusing element positioned above the photovoltaic device and the maximum translation position is a position approximately half way between the home positions of adjacent photovoltaic devices.

19. The assembly of claim 16, wherein at neither the home position nor the maximum translation position is the photovoltaic device axially aligned with a light focusing element.

20. The assembly of claim 15, further comprising:
a photovoltaic platform configured to support the array of photovoltaic devices; and
wherein the photovoltaic platform is configured to raise and lower the array of photovoltaic devices relative to the array of light focusing elements.

21. The assembly of claim 15, further comprising:
a photovoltaic platform configured to support the array of photovoltaic devices;
wherein the photovoltaic platform is configured to change an angular position of the photovoltaic devices relative to the light focusing elements.

22. The assembly of claim 21, wherein the photovoltaic platform is configured to change the angular position in two dimensions.

23. The assembly of claim 21, wherein the photovoltaic platform is further configured to raise and lower the array of photovoltaic devices relative to the array of light focusing elements.

24. The assembly of claim 1, wherein each light focusing element comprises:
an electro-optic prism operable to provide controllable steering of solar rays incident on the receiving surface of the light focusing element; and
a lens arranged in optical communication with the electro-optic prism and positioned to receive and concentrate the solar rays after having passed through the electro-optic prism;
wherein:
solar rays incident on the receiving surface of the light focusing element between an angle of −θ to θ from an axis perpendicular to the receiving surface are controllably steered by the electro-optic prism such that said solar rays are incident on the lens at a substantially right angle to a receiving surface of the lens and are concentrated by the lens on a first photovoltaic device

25. The assembly of claim 24, wherein solar rays incident on the receiving surface of the light focusing element between angles of −3θ to −θ and θ to 3θ from an axis perpendicular to the receiving surface are controllably steered by the electro-optic prism such that said solar rays are incident on the lens at an oblique angle and concentrated by the lens on a neighboring second photovoltaic device.

26. The assembly of claim 24, wherein the electro-optic prism comprises:
a first electrode comprising a plurality of substantially parallel linear electrodes positioned on a first substrate;
a reference electrode positioned on a second substrate; and
an electro-optic material positioned between the first electrode and the reference electrode.

27. The assembly of claim 26, wherein the electro-optic material comprises a layer having a substantially uniform thickness.

28. The assembly of claim 26, wherein the electro-optic material comprises a liquid crystal material.

29. The assembly of claim 26, wherein the electro-optic material is positioned between the first electrode and the reference electrode such that, where separately controllable voltages are provided to at least some of the linear electrodes, a gradient electric field is provided within the electro-optic material to cause the electro-optic material to have a refractive index gradient and wherein the refractive index gradient can be controlled by varying the magnitude of the separately controllable voltages provided to at least some of the linear electrodes.

30. The assembly of claim 24, wherein steering of solar rays incident on the electro-optic prism is controllable by controlling the refractive index gradient.

31. The assembly of claim 24, further comprising:
a set of corrective optics orientated substantially perpendicular to the arrays of light focusing elements and photovoltaic devices and positioned periodically in a space therebetween.

32. The assembly of claim 31, wherein the corrective optics include one or more Fresnel lens.

33. A light energy collection system, comprising:
an array of light focusing elements;
an array of photovoltaic devices; and
a translation mechanism;
wherein the translation mechanism is configured to translate the array of light focusing elements and the array of photovoltaic devices relative to one another based on an incidence angle of light rays impinging on receiving surfaces of the light focusing elements such that the light rays can be continually concentrated by the light focusing elements on a photovoltaic device included in the array of photovoltaic devices as a source of the light rays moves relative to the system.

34. The system of claim 33, wherein the array of light focusing elements is fixed and the translation mechanism is configured to translate the array of photovoltaic devices.

35. The system of claim 33, wherein the array of photovoltaic devices is fixed and the translation mechanism is configured to translate the array of light focusing elements.

36. The system of claim 33, wherein neither the array of light focusing elements nor the array of photovoltaic devices is fixed and the translation mechanism is configured to translate both arrays.

37. The assembly of claim 33, wherein each photovoltaic device has a home position and a maximum translation position and wherein the translation mechanism is configured to translate the photovoltaic devices from the home position to the maximum translation position and then return the photovoltaic devices to the home position.

38. The assembly of claim 37, wherein the home position is a position such that the photovoltaic device is substantially axially aligned with a light focusing element positioned above the photovoltaic device and the maximum translation position is a position approaching the home position of an adjacent photovoltaic device.

39. The assembly of claim 37, wherein the home position is a position such that the photovoltaic device is substantially axially aligned with a light focusing element positioned above the photovoltaic device and the maximum translation position is a position approximately half way between the home positions of neighboring photovoltaic devices.

40. The assembly of claim 37, wherein at neither the home position nor the maximum translation position is the photovoltaic device axially aligned with a light focusing element.

41. The assembly of claim 33, further comprising:
a photovoltaic platform configured to support the array of photovoltaic devices; and
wherein the photovoltaic platform is configured to raise and lower the array of photovoltaic devices relative to the array of light focusing elements.

42. The assembly of claim 33, further comprising:
a photovoltaic platform configured to support the array of photovoltaic devices;
wherein the photovoltaic platform is configured to change an angular position of the photovoltaic devices relative to the light focusing elements.

43. The assembly of claim 42, wherein the photovoltaic platform is configured to change the angular position in two dimensions.

44. The assembly of claim 33, wherein the photovoltaic platform is further configured to raise and lower the array of photovoltaic devices relative to the array of light focusing elements based on the incidence angle of the light rays on the receiving surfaces of the light focusing elements.

45. A method of concentrating light rays from a moving light source onto a photovoltaic device, comprising:
receiving light rays on receiving surfaces of light focusing elements comprising an array of light focusing elements;
concentrating the light rays onto a photovoltaic device included in an array of photovoltaic devices positioned beneath the array of light focusing elements; and
as an incidence angle of the light rays on the receiving surfaces changes due to movement of the light source, translating the array of light focusing elements relative to the array of photovoltaic devices such that the light rays remain impingent on a photovoltaic device.

46. The method of claim 45, wherein the array of light focusing elements is fixed and the array of photovoltaic devices is translated.

47. The method of claim 45, wherein the array of photovoltaic devices is fixed and the array of light focusing elements is translated.

48. The method of claim 45, wherein translating the array of light focusing elements relative to the array of photovoltaic devices comprises translating both arrays.

49. The method of claim 45, wherein the light rays exiting from a first light focusing element included in the array are concentrated on a first photovoltaic device when the incidence angle is within a first range of angles and are concentrated on an adjacent second photovoltaic device when the incidence angle is within a second range of angles.

50. The method of claim 49, wherein the light rays from the first light focusing element are concentrated on a third photovoltaic device adjacent to the second photovoltaic device when the incidence angle is within a third range of angles.

51. A method of concentrating light rays from a moving light source onto a photovoltaic device, comprising:
receiving light rays on receiving surfaces of light focusing elements comprising an array of light focusing elements;
concentrating the light rays onto a photovoltaic device included in an array of photovoltaic devices positioned beneath the array of light focusing elements;
wherein each light focusing element includes an electro-optic prism and a lens, where the electro-optic prism is configured to steer light rays incident on the light focusing element so as to impinge on the lens at an angle such that light rays exiting the lens are focused on a photovoltaic device included in the array of photovoltaic devices.

52. The method of claim 51, further comprising:
applying voltages to the electro-optic prism to (i) control a refractive index of the electro-optic prism; and (ii) controllably steer the light rays; wherein the electro-optic prism comprises a layer of electro-optic material having a substantially uniform thickness.

53. The method of claim 52, wherein the electro-optic material comprises a liquid crystal material.

54. The method of claim 52, wherein the lens comprises a Fresnel lens.

55. The method of claim 51, wherein the light rays exiting from a first light focusing element included in the array are concentrated on a first photovoltaic device when the incidence angle is within a first range of angles and are concentrated on an adjacent second photovoltaic device when the incidence angle is within a second range of angles.

56. The method of claim 51, wherein:
the electro-optic prism is configured to steer light rays incident on a first light focusing element so as to impinge on the lens at approximately normal to an optical axis of the lens when the incidence angle is within a first range of angles;
light rays exiting from the first light focusing element when the incidence angle is within the first range of angles are incident on a first photovoltaic device positioned beneath and axially aligned with the lens;
the electro-optic prism is configured to steer light rays incident on the first light focusing element so as to impinge on the lens at an angle oblique to the optical axis of the lens when the incidence angle is within a second range of angles; and
light rays exiting from the first light focusing element when the incidence angle is within the second range of angles are incident on a second photovoltaic device positioned adjacent the first photovoltaic device.

57. The method of claim 56, wherein:
the electro-optic prism is configured to steer light rays incident on the first light focusing element so as to impinge on the lens at an angle oblique to the optical axis of the lens when the incidence angle is within a third range of angles, where the third range of angles are more oblique than the second range of angles; and
light rays exiting from the first light focusing element when the incidence angle is within the third range of angles are incident on a third photovoltaic device positioned adjacent the second photovoltaic device.
